(19) United States
(12) Patent Application Publication
(10) Pub. No.: US 2026/0304867 A1
(43) Pub. Date: Oct. 1, 2026

(54) THREE DIMENSIONAL INTEGRATED CIRCUIT AND FABRICATION THEREOF

(71) Applicants: TAIWAN SEMICONDUCTOR MANUFACTURING COMPANY, LTD., Hsinchu (TW); NATIONAL YANG MING CHIAO TUNG UNIVERSITY, Hsinchu City (TW)

(72) Inventors: Chenming HU, Oakland, CA (US); Kuan-Neng CHEN, Hsinchu City (TW); Po-Tsang HUANG, Hsinchu City (TW); Bo-Jheng SHIH, Kaohsiung City (TW); Yu-Ming PAN, New Taipei City (TW); Ching-Lin CHEN, Taichung City (TW)

(73) Assignees: TAIWAN SEMICONDUCTOR MANUFACTURING COMPANY, LTD., Hsinchu (TW); NATIONAL YANG MING CHIAO TUNG UNIVERSITY, Hsinchu City (TW)

(21) Appl. No.: 19/280,595

(22) Filed: Jul. 25, 2025

Related U.S. Application Data
(60) Provisional application No. 63/779,414, filed on Mar. 28, 2025.

(51) Int. Cl. H10D 62/10; H01L 21/02; H01L 23/522; H01L 23/528; H10D 30/62; H10D 62/13; H10D 62/83; H10D 84/83

(52) U.S. Cl. CPC H10D 62/126; H10D 30/6212; H10D 62/151; H10D 62/83; H10D 84/834; H10P 14/3814; H10P 14/3816; H10W 20/42; H10W 20/435

(57) ABSTRACT

An IC structure includes a first transistor, a dielectric layer, a plurality of first semiconductor pillars, a semiconductor structure, and a second transistor. The first transistor is formed on a substrate. The dielectric layer is above the first transistor. The first semiconductor pillars are disposed over the substrate and extend through the dielectric layer. The semiconductor structure is disposed over the top surface of the dielectric layer. The second transistor is formed on the semiconductor structure.

### PRIORITY CLAIM AND CROSS-REFERENCE

This application claims priority to U.S. Provisional Application Ser. No. 63/779,414, filed Mar. 28, 2025, which is herein incorporated by reference.

### BACKGROUND

The semiconductor industry has experienced rapid growth due to continuous improvements in the integration density of various electronic components (i.e., transistors, diodes, resistors, capacitors, etc.). For the most part, this improvement in integration density has come from repeated reductions in minimum feature size, which allows more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2A, 3A, 3B, 4A, 4B, 5, 6A, 7, 8, 9A, 9C, 11 and 12 illustrate cross-sectional views at intermediate stages of a method of forming a 3D IC structure in accordance with some embodiments.

FIGS. 2B, 2C, 3C, 3D illustrate top views at intermediate stages of a method of forming a 3D IC structure in accordance with some embodiments.

FIG. 6B illustrates a sample for performing an laser anneal in accordance with some embodiments.

FIGS. 6C and 6D are graphs illustrating example experiment results of the laser anneal, in accordance with some embodiments.

FIG. 6E illustrates a perspective view of an example flat-top laser generator suitable for use in laser anneal processes that achieves the experimental results illustrated in FIGS. 6C-6D, in accordance with some embodiments.

FIG. 6F illustrates a three-dimensional representation of an intensity profile of a laser beam generated by the flat-top laser generator as illustrated in FIG. 6E, in accordance with some embodiments.

FIG. 6G illustrates a cross-sectional intensity profile of the laser beam of FIG. 6F along the x-axis, corresponding to the horizontal direction of the irradiated region in a top view, in accordance with some embodiments.

FIG. 6H illustrates a cross-sectional intensity profile of the laser beam of FIG. 6F along the y-axis, corresponding to the vertical direction of the irradiated region in a top view, in accordance with some embodiments.

FIGS. 9B and 10 illustrate perspective views at intermediate stages of a method of forming a 3D IC structure in accordance with some embodiments.

FIGS. 13, 14A, 15, 16, 17, 18, 19A, 19C, 21, and 22 illustrate cross-sectional views at intermediate stages of a method of forming a 3D IC structure in accordance with some embodiments.

FIGS. 14B and 14C illustrate top views at intermediate stages of a method of forming a 3D IC structure in accordance with some embodiments.

FIGS. 19B and 20 illustrates a perspective view at an intermediate stage of a method of forming a 3D IC structure in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Integrated circuit (IC) devices integration improvements are essentially two-dimensional (2D) in nature, in that the volume occupied by the integrated components is essentially on the surface of the semiconductor wafer. Although dramatic improvement in lithography has resulted in considerable improvement in 2D IC formation, there are physical limits to the density that can be achieved in two dimensions. One of these limits is the minimum size needed to make these components. Also, when more devices are put into one chip, more complex designs are used. Therefore, the present disclosure, in various embodiments, provides a three-dimensional (3D) IC structure having lower transistors at a lower level and higher transistors at a higher level, which in turn significantly improves the device density in a given area.

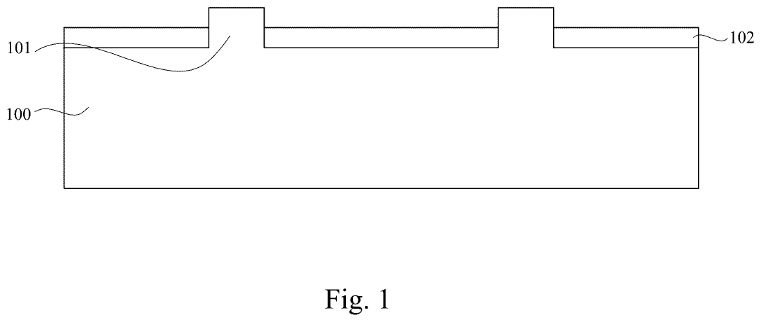

FIGS. 1-12 illustrate intermediate stages of a method of forming a 3D IC structure in accordance with some embodiments. Although the cross-sectional views shown in FIGS. 1-12 are described with reference to a method, it will be appreciated that the structures shown in FIGS. 1-12 are not limited to the method but rather may stand alone separate of the method. Although FIGS. 1-12 are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

FIG. 1 is a cross-sectional view of an example initial structure comprising a semiconductor substrate 100, semiconductor pillars 101 extending from the substrate 100, and shallow trench isolation (STI) regions 102 formed around sidewalls of the semiconductor pillars 101. The substrate 100 may comprise a bulk semiconductor substrate or a silicon-on-insulator (SOI) substrate. An SOI substrate includes an insulator layer below a thin semiconductor layer that is the active layer of the SOI substrate. The semiconductor of the active layer and the bulk semiconductor generally comprise the crystalline semiconductor material silicon, but may include one or more other semiconductor materials such as germanium, silicon-germanium alloys, compound semiconductors (e.g., GaAs, AlAs, InAs, GaN, AlN, and the like), or their alloys (e.g., GaₓAl₁₋ₓAs, GaₓAl₁₋ₓN, InₓGa₁₋ₓAs and the like), or combinations thereof. The semiconductor materials may be doped or undoped. Other substrates that may be used include multi-layered substrates, gradient substrates, or hybrid orientation substrates. In some embodiments, the top-view pattern or plan-view pattern of the semiconductor pillars 101 can be rectangular, circular, linear, L-shaped, T-shaped, or other shapes. In some embodiments, the semiconductor pillars 101 may be arranged in a hexagonal, parallelogram, or other complex geometric pattern.

Shallow trench isolation (STI) regions 102 formed around sidewalls of the semiconductor pillars 101. STI regions 102 may be formed by depositing one or more dielectric materials (e.g., silicon oxide) to completely fill the trenches around the fins and then recessing the top surface of the dielectric materials. The dielectric materials of the STI regions 102 may be deposited using a high density plasma chemical vapor deposition (HDP-CVD), a low-pressure CVD (LPCVD), sub-atmospheric CVD (SACVD), a flowable CVD (FCVD), spin-on, and/or the like, or a combination thereof. After the deposition, an anneal process or a curing process may be performed. In some cases, the STI regions 102 may include a liner such as, for example, a thermal oxide liner grown by oxidizing the silicon surface. The recess process may use, for example, a planarization process (e.g., a chemical mechanical polish (CMP)) followed by a selective etch process (e.g., a wet etch, or dry etch, or a combination thereof) that may recess the top surface of the dielectric materials in the STI region 102 such that upper portions of semiconductor pillars 101 protrude from surrounding insulating STI regions 102.

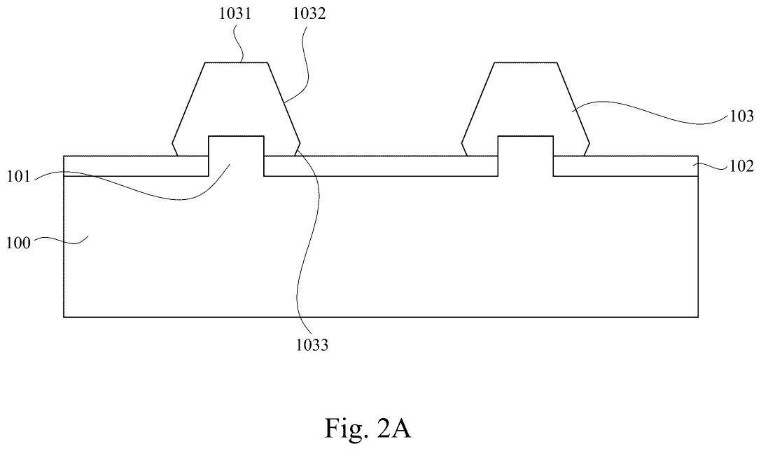

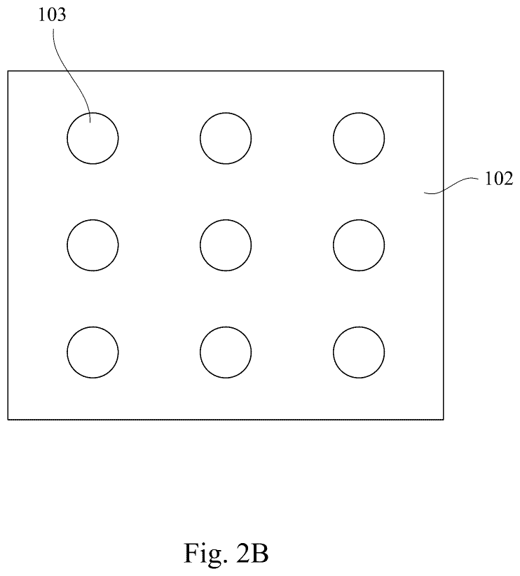

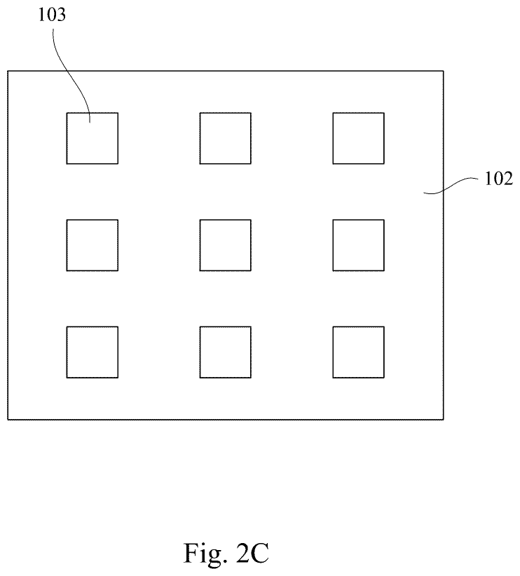

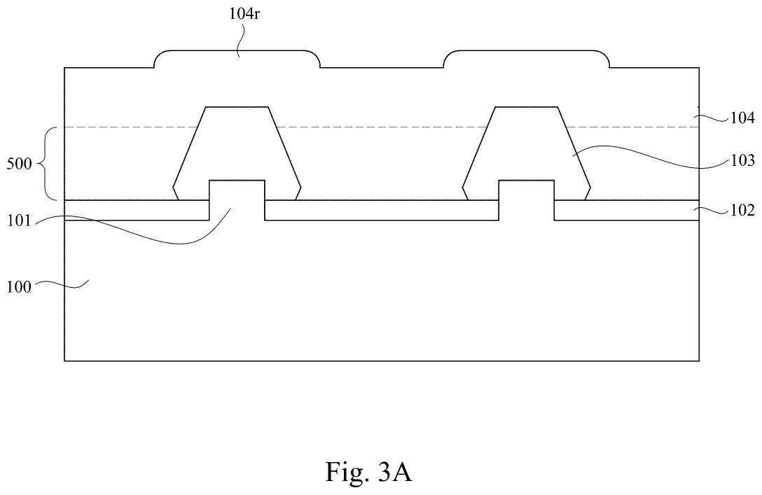

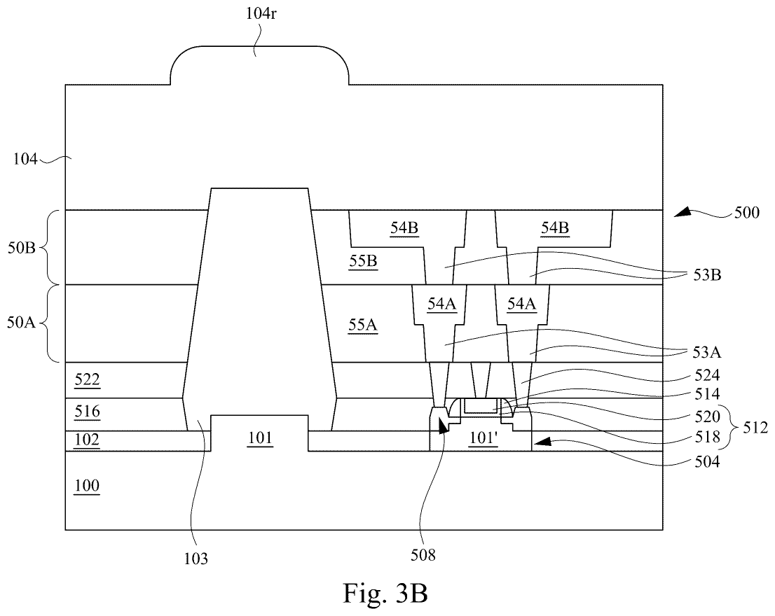

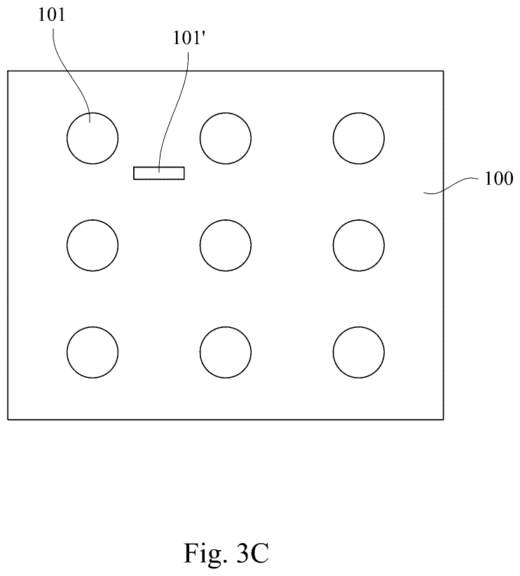

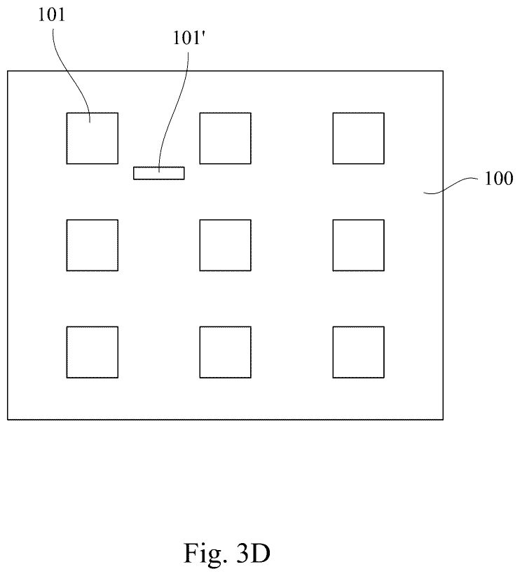

In FIG. 2A, single-crystalline raised semiconductor pillars 103 are epitaxially grown from upper portions of the semiconductor pillars 101. In some embodiments, the single-crystalline raised semiconductor pillars 103 are grown using selective epitaxial growth (SEG). Specifically, epitaxial semiconductor material, such as silicon, germanium, or silicon germanium (SiₓGe₁₋ₓ), is deposited under process conditions that promote crystal growth selectively on the exposed surfaces of semiconductor pillars 101, not on the STI regions 102. The SEG process leverages the inherent differences in surface energy and lattice structure between the single-crystalline surfaces of semiconductor pillars 101 and the amorphous surfaces of STI regions 102, allowing that the epitaxial growth proceeds only from the single-crystalline surfaces and not on the amorphous surfaces. In some embodiments, the resulting raised semiconductor pillars 103 inherit the lattice orientation of the underlying semiconductor pillars 101. In some embodiments, the semiconductor pillars 101 may be recessed, followed by growing the raised semiconductor pillars 103 in the recessed regions of the semiconductor pillars 101. In some embodiments, during the epitaxial growth of the raised semiconductor pillars 103, a soft or hard mask can be formed covering the fin 101′ (as illustrated in FIG. 3B), so as to prevent epitaxial semiconductor material from forming on the fin 101′ during the epitaxial growth of the raised semiconductor pillars 103.

In some embodiments, the SEG process may utilize various epitaxial methods, including vapor phase epitaxy (VPE), metal-organic chemical vapor deposition (MOCVD), or molecular beam epitaxy (MBE). During the SEG process, precursor gases such as silane (SiH₄), disilane (Si₂H₆), germane (GeH₄), or their mixtures are introduced into a CVD reactor. The process is conducted at a temperature and pressure regime tuned to promote epitaxial nucleation and growth selectively on the exposed semiconductor surfaces, while suppressing nucleation on the dielectric surfaces. This selectivity is achieved by exploiting the substantial difference in surface energy and chemical reactivity between the single-crystalline semiconductor and the amorphous dielectric. As a result, the epitaxial materials grow selectively from semiconductor pillars 101, forming single-crystalline raised semiconductor pillars 103 that replicate the lattice structure of the underlying pillars 101.

In some embodiments, the single-crystalline raised semiconductor pillars 103 exhibit a faceted morphology, comprising distinct crystallographic planes that form during the SEG process. As shown in FIG. 2A, the faceted structure of each single-crystalline raised semiconductor pillar 103 includes a top horizontal facet 1031, up-slant facets 1032, and down-slant facets 1033. The top horizontal facet 1031 is generally parallel to the surface of substrate 100 and corresponds to a low-index crystallographic plane, such as the (001) plane in the case of a silicon pillar grown on a (001)-oriented substrate. This facet forms the uppermost surface of the raised pillar 103 and provides a planar region suitable for subsequent processing steps. The up-slant facets 1032 extend outward from the edges of the top horizontal facet 1031. These up-slant facets 1032 may be inclined with respect to the surface of substrate 100 and may correspond to crystallographic planes such as {111}, depending on the growth conditions and the material system. The formation of up-slant facets 1032 is driven by the minimization of surface free energy during the SEG process, resulting in stable and well-defined facet angles. The down-slant facets 1033 extend downwardly from the up-slant facets 1032 to the STI regions 102. The down-slant facets 1033 may also correspond to specific crystallographic planes different than the (001) plane, and their formation is influenced by the interplay between vertical and lateral growth rates during the SEG process. In some embodiments, the raised semiconductor pillars 103 may have a diamond or hexagon shape in a cross-sectional view.

In some embodiments, as illustrated in the cross-sectional view in FIG. 2A, the up-slant facets 1032 are larger than the down-slant facets 1033 and the top horizontal facet 1031, and the top horizontal facet 1031 is larger than the down-slant facet 1033. This distinction in facet size may arise from the intrinsic kinetics of the SEG process, as well as the crystallographic orientation of the underlying semiconductor substrate 100 and the specific process parameters employed. In some embodiments, the top-view pattern or plan-view pattern of the raised semiconductor pillars 103 can be rectangular, circular, linear, L-shaped, T-shaped, or other shapes. In some embodiments, the semiconductor pillars 103 are arranged equidistantly in rows and columns, as illustrated in the top view of FIG. 2B. The raised semiconductor pillars 103 each have a circular or elliptic top-view profile, as illustrated in the top view of FIG. 2B. In some other embodiments, the raised semiconductor pillars 103 each have a quadrilateral or square top-view profile as illustrated in FIG. 2C.

In some embodiments, the pitch of the raised semiconductor pillars 103 (e.g., center-to-center distance of adjacent pillars 103) may be greater than or equal to 500 nm. In some embodiments, the ratio of the lateral dimension (e.g., width or diameter) of the single-crystalline raised semiconductor pillars 103 or semiconductor pillars 101 to the pitch of the corresponding pillars is less than 1.

In FIG. 3A, a lower-level circuit structure 500 is formed over the substrate 100, and an interlayer dielectric (ILD) layer 104 is formed over the lower-level circuit structure 500 and the single-crystalline semiconductor pillars 103. FIG. 3B illustrates a cross-sectional view of example details of the lower-level circuit structure 500, comprising various electronic devices formed over the substrate 100, and a multilevel interconnect structure (e.g., metallization layers 50A and 50B) formed over the substrate 100, in accordance with some embodiments. Generally, FIG. 3B illustrates a transistor 504 formed on the substrate 100, with multiple interconnection layers formed thereover. Multiple interconnect levels (e.g., a plurality of layers 50B stacked one above another) may be similarly stacked in the fabrication process of an integrated circuit. In the illustrated embodiments, the transistor 504 is a FinFET. In some other embodiments, the transistor 504 is a planar FET, a gate-all-around (GAA) FET, a nanosheet FET, a nanowire FET, or other suitable FET. Transistors 504 and the overlying interconnect wires in the multilevel interconnect structure can be electrically coupled to function as, for example, logic circuits or other circuits.

In some embodiments, the FinFET device 504 illustrated in FIG. 3B is a three-dimensional MOSFET structure formed in fin-like strips of semiconductor protrusions 101′ referred to as fins. The cross-section shown in FIG. 3B is taken along a longitudinal axis of the fin 101′ in a direction parallel to the direction of the current flow between source and drain regions 508 of the FinFET device 504. FIG. 3B illustrates a single fin 101′, although the substrate 100 may comprise any number of fins.

In some embodiments, the semiconductor pillars 101 and semiconductor fins 101′ are formed by patterning the substrate 100 in the same photolithography and etching steps and thus have top surfaces at the same level. However, the semiconductor pillars 101 serve for a different role for the semiconductor fins 101'. Therefore, the semiconductor pillars 101 may have a different top-view pattern than the semiconductor fins 101′. For example, the top-view pattern or plan-view pattern of the semiconductor pillars 101 can be rectangular, circular, linear, L-shaped, T-shaped, or other shapes, and the top-view pattern or plan-view pattern of the semiconductor fins 101′ can be linear. In some embodiments, the semiconductor pillars 101 are arranged equidistantly in rows and columns, as illustrated in the top view of FIG. 3C. The semiconductor pillars 101 each have a circular or elliptic top-view profile, which is different from the strip-shaped top-view profile of semiconductor fins 101′ (only one fin is illustrated for the sake of brevity), as illustrated in the top view of FIG. 3C. In some other embodiments, the semiconductor pillars 101 each have a quadrilateral or square top-view profile, which is different from the strip-shaped top-view profile of semiconductor fins 101′, as illustrated in FIG. 3D. The semiconductor pillar 101 has a top-view area different from a top-view area of the semiconductor fin 101′.

The raised semiconductor pillars 103 extend from the substrate 100 to above the topmost position of the lower-level circuit structure 500, and thus the semiconductor pillars 103 have heights much greater than heights of the semiconductor fins 101′. For example, a ratio of a height of raised semiconductor pillar 103 to a height of semiconductor fin 101′ is greater than 5, 6, 7, 8, 9, 10, or more. Such a height difference allows for melting a semiconductor material subsequently formed over the lower-level circuit structure 500, while not melting materials of the lower-level circuit structure 500, e.g., semiconductor materials of the transistors 504. In some embodiments, the raised semiconductor pillar 103 has a height H₁₀₃ in a range from about 0.1 to about 1 μm. In some embodiments, the semiconductor pillar height H₁₀₃ is greater than 200 nm.

In some embodiments, the gate structure 512 of the FinFET device 504 illustrated in FIG. 3B is a high-k, metal gate (HKMG) gate structure that may be formed using a gate-last process flow. In a gate last process flow a sacrificial dummy gate structure (not shown) is formed after forming the STI regions 102. The dummy gate structure may comprise a dummy gate dielectric, a dummy gate electrode, and a hard mask. First a dummy gate dielectric material (e.g., silicon oxide, silicon nitride, or the like) may be deposited. Next a dummy gate material (e.g., amorphous silicon, polycrystalline silicon, or the like) may be deposited over the dummy gate dielectric. A hard mask layer (e.g., silicon nitride, silicon carbide, or the like) may be formed over the dummy gate material. The dummy gate structure is then formed by patterning the hard mask and transferring that pattern to the dummy gate dielectric and dummy gate material using suitable photolithography and etching techniques. The dummy gate structure may extend along multiple sides of the protruding fins 101′ and extend between the fins over the surface of the STI regions 102. As described in greater detail below, the dummy gate structure may be replaced by the HKMG gate structure 512 as illustrated in FIG. 3B. The materials used to form the dummy gate structure and hard mask may be deposited using any suitable method such as CVD, plasma-enhanced CVD (PECVD), atomic layer deposition (ALD), plasma-enhanced ALD (PEALD) or the like, or by thermal oxidation of the semiconductor surface, or combinations thereof.

Source and drain regions (collectively referred to as “source/drain regions” or “S/D regions”) 508 and spacers 514 of FinFET 504, illustrated in FIG. 3B, are formed, for example, self-aligned to the dummy gate structures. Spacers 514 may be formed by deposition and anisotropic etch of a spacer dielectric layer performed after the dummy gate patterning is complete. The spacer dielectric layer may include one or more dielectrics, such as silicon oxide, silicon nitride, silicon oxynitride, silicon carbide, silicon carbonitride, the like, or a combination thereof. The anisotropic etch process removes the spacer dielectric layer from over the top of the dummy gate structures leaving the spacers 514 along the sidewalls of the dummy gate structures.

Source and drain regions 508 are semiconductor regions interfacing the semiconductor fin 101′. In some embodiments, the source and drain regions 508 may comprise heavily-doped regions and relatively lightly-doped drain extensions, or LDD regions. Generally, the heavily-doped regions are spaced away from the dummy gate structures using the spacers 514, whereas the LDD regions may be formed prior to forming spacers 514 and, hence, extend under the spacers 514 and, in some embodiments, extend further into a portion of the semiconductor fin 101′ below the dummy gate structure. The LDD regions may be formed, for example, by implanting dopants (e.g., As, P, B, In, or the like) using an ion implantation process.

In some embodiments, the source and drain regions 508 may comprise an epitaxially grown region. For example, after forming the LDD regions, the spacers 514 may be formed and, subsequently, the heavily-doped source and drain regions may be formed self-aligned to the spacers 514 by first etching the fins 101′ to form recesses, and then depositing a crystalline semiconductor material in the recess by a selective epitaxial growth (SEG) process that may fill the recess and, typically, extend beyond the original surface of the fin to form a raised source-drain structure, as illustrated in FIG. 3B. The crystalline semiconductor material may be elemental (e.g., Si, or Ge, or the like), or an alloy (e.g., Si₁₋ₓCₓ, or Si₁₋ₓGeₓ, or the like). The SEG process may use any suitable epitaxial growth method, such as e.g., vapor/solid/liquid phase epitaxy (VPE, SPE, LPE), or metal-organic CVD (MOCVD), or molecular beam epitaxy (MBE), or the like. A high dose (e.g., from about 10¹⁵ cm⁻² to 10¹⁸ cm⁻²) of dopants may be introduced into the heavily-doped source and drain regions 508 either in situ during SEG, or by an ion implantation process performed after the SEG, or by a combination thereof. In some embodiments, the semiconductor pillars 103 may be covered with a mask (e.g., photoresist mask or hard mask) before forming the source/drain regions 508, and then the mask can be removed after the source/drain regions are 508 are formed.

A first interlayer dielectric (ILD) 516 is deposited over the structure. In some embodiments, a contact etch stop layer (CESL) (not shown) of a suitable dielectric (e.g., silicon nitride, silicon carbide, or the like, or a combination thereof) may be deposited prior to depositing the ILD material. A planarization process (e.g., selective etch back) may be performed to remove excess ILD material and any remaining hard mask material from over the dummy gates to form a top surface wherein the top surface of the dummy gate material is exposed and may be substantially coplanar with the top surface of the first ILD 516. The HKMG gate structures 512, illustrated in FIG. 3B, may then be formed by first removing the dummy gate structures using one or more etching techniques, thereby creating trenches between respective spacers 514. Next, a replacement gate dielectric layer 518 comprising one more dielectrics, followed by a replacement conductive gate layer 520 comprising one or more conductive materials, are deposited to completely fill the recesses. Excess portions of the gate structure layers 518 and 520 may be removed from over the top surface of first ILD 516 using, for example, a selective etch back process. By utilizing selective etching, it is possible to substantially avoid or minimize physical or chemical damage to the raised semiconductor pillars 103, which may otherwise occur during alternative planarization processes, such as chemical mechanical polishing (CMP). The resulting structure, as illustrated in FIG. 3B, may be a substantially coplanar surface comprising an exposed top surface of first ILD 516, spacers 514, and remaining portions of the HKMG gate layers 518 and 520 inlaid between respective spacers 514.

The gate dielectric layer 518 includes, for example, a high-k dielectric material such as oxides and/or silicates of metals (e.g., oxides and/or silicates of Hf, Al, Zr, La, Mg, Ba, Ti, and other metals), silicon nitride, silicon oxide, and the like, or combinations thereof, or multilayers thereof. In some embodiments, the conductive gate layer 520 may be a multilayered metal gate stack comprising a barrier layer, a work function layer, and a gate-fill layer formed successively on top of gate dielectric layer 518. Example materials for a barrier layer include TiN, TaN, Ti, Ta, or the like, or a multilayered combination thereof. A work function layer may include TiN, TaN, Ru, Mo, Al, for a p-type FET, and Ti, Ag, TaAl, TaAlC, TiAlN, TaC, TaCN, TaSiN, Mn, Zr, for an n-type FET. Other suitable work function materials, or combinations, or multilayers thereof may be used. The gate-fill layer which fills the remainder of the recess may comprise metals such as Cu, Al, W, Co, Ru, or the like, or combinations thereof, or multi-layers thereof. The materials used in forming the gate structure may be deposited by any suitable method, e.g., CVD, PECVD, physical vapor deposition (PVD), ALD, PEALD, electrochemical plating (ECP), electroless plating and/or the like.

A second ILD layer 522 may be deposited over the first ILD layer 516, as illustrated in FIG. 3B. In some embodiments, the insulating materials to form the first ILD layer 516 and the second ILD layer 522 may comprise silicon oxide, phosphosilicate glass (PSG), borosilicate glass (BSG), boron-doped phosphosilicate glass (BPSG), undoped silicate glass (USG), a low dielectric constant (low-k) dielectric such as, fluorosilicate glass (FSG), silicon oxycarbide (SiOCH), carbon-doped oxide (CDO), flowable oxide, or porous oxides (e.g., xerogels/aerogels), or the like, or a combination thereof. The dielectric materials used to form the first ILD layer 516 and the second ILD layer 522 may be deposited using any suitable method, such as CVD, physical vapor deposition (PVD), ALD, PEALD, PECVD, SACVD, FCVD, spin-on, and/or the like, or a combination thereof. A selective etch back process may be performed on the deposited ILD layer 522 such that upper portions of semiconductor pillars 103 protrude from the second ILD layer 522.

As illustrated in FIG. 3B, electrodes of electronic devices formed in the substrate 100 may be electrically connected to conductive features of a first interconnect level 50A using conductive connectors (e.g., contacts 524) formed through the intervening dielectric layers. In the embodiment illustrated in FIG. 3B, some contacts 524 make electrical connections to the source and drain regions 508 of FinFETs 504 and can be referred to as source/drain contacts, some contacts 524 make electrical connections to gate structures 512 of FinFETs 504 and can be referred to as gate contacts. The contacts may be formed using photolithography techniques. For example, a patterned mask may be formed over the second ILD 522 and used to etch openings that extend through the second ILD 522 to expose a portion of gate structures 512, as well as etch openings that extend further through the first ILD 516 and the CESL (if present) liner below first ILD 516 to expose portions of the source and drain regions 508.

In some embodiments, a conductive liner may be formed in the openings in the first ILD layer 516 and the second ILD layer 522. Subsequently, the openings are filled with a conductive fill material. The liner comprises barrier metals used to reduce out-diffusion of conductive materials from the contacts 524 into the surrounding dielectric materials. In some embodiments, the liner may comprise two barrier metal layers. The first barrier metal comes in contact with the semiconductor material in the source and drain regions 508 and may be subsequently chemically reacted with the heavily-doped semiconductor in the source and drain regions 508 to form a low resistance ohmic contact, after which the unreacted metal may be removed. For example, if the heavily-doped semiconductor in the source and drain regions 508 is silicon or silicon-germanium alloy semiconductor, then the first barrier metal may comprise Ti, Ni, Pt, Co, other suitable metals, or their alloys. The second barrier metal layer of the conductive liner may additionally include other metals (e.g., TiN, TaN, Ta, or other suitable metals, or their alloys). A conductive fill material (e.g., W, Al, Cu, Ru, Ni, Co, alloys of these, combinations thereof, and the like) may be deposited over the conductive liner layer to fill the contact openings, using any acceptable deposition technique (e.g., CVD, ALD, PEALD, PECVD, PVD, ECP, electroless plating, or the like, or any combination thereof). Next, a selective etch back process may be used to remove excess portions of all the conductive materials from over the surface of the second ILD 522. The resulting conductive plugs extend into the first and second ILD layers 516 and 522 and constitute contacts 524 making physical and electrical connections to the electrodes of electronic devices, such as the tri-gate FinFET 504 illustrated in FIG. 3B. By utilizing selective etching to remove excess portions of all the conductive materials from over the surface of the second ILD 522, it is possible to substantially avoid or minimize physical or chemical damage to the raised semiconductor pillars 103, which may otherwise occur during alternative planarization processes, such as chemical mechanical polishing (CMP).

As illustrated in FIG. 3B, multiple interconnect levels may be formed, stacked vertically above the contact plugs 524 formed in the first and second ILD layers 516 and 522, in accordance with a back end of line (BEOL) scheme adopted for the integrated circuit design. In the BEOL scheme illustrated in FIG. 3B, various interconnect levels have similar features. However, it is understood that other embodiments may utilize alternate integration schemes wherein the various interconnect levels may use different features. For example, the contacts 524, which are shown as vertical connectors, may be extended to form conductive lines which transport current laterally.

In this disclosure, the interconnect level comprises conductive vias and lines embedded in an inter-metal dielectric (IMD) layer. In addition to providing insulation between various conductive elements, an IMD layer may include one or more dielectric etch stop layers to control the etching processes that form openings in the IMD layer. Generally, vias conduct current vertically and are used to electrically connect two conductive features located at vertically adjacent levels, whereas lines conduct current laterally and are used to distribute electrical signals and power within one level. In the BEOL scheme illustrated in FIG. 3B, conductive vias 53A connect contacts 524 to conductive lines 54A and, at subsequent levels, vias connect lower lines to upper lines (e.g., lines 54A and 54B can be connected by via 53B). Other embodiments may adopt a different scheme. For example, vias 53A may be omitted from the second level and the contacts 524 may be configured to be directly connected to lines 54A.

The first interconnect level 50A may be formed using, for example, a dual damascene process flow. First, a dielectric stack used to form IMD layer 55A may be deposited using one or more layers of the dielectric materials listed in the description of the first and second ILD layers 516 and 522. In some embodiments, IMD layer 55A includes an etch stop layer (not shown) positioned at the bottom of the dielectric stack. The etch stop layer comprises one or more insulator layers (e.g., SiN, SiC, SiCN, SiCO, CN, combinations thereof, or the like) having an etch rate different than an etch rate of an overlying material. The techniques used to deposit the dielectric stack for IMD may be the same as those used in forming the first and second ILD layers 516 and 522. In some embodiments, after depositing the dielectric stack for IMD, a selective etch back process may be performed on the deposited dielectric materials such that upper portions of semiconductor pillars 103 protrude from the dielectric materials.

Appropriate photolithography and etching techniques (e.g., anisotropic RIE employing fluorocarbon chemistry) may be used to pattern the IMD layer 55A to form openings for vias and lines. The openings for vias may be vertical holes extending through IMD layer 55A to expose a top conductive surface of contacts 524, and openings for lines may be longitudinal trenches formed in an upper portion of the IMD layer 55A. In some embodiments, the method used to pattern holes and trenches in IMD 55A utilizes a via-first scheme, wherein a first photolithography and etch process form holes for vias, and a second photolithography and etch process form trenches for lines. Other embodiments may use a different method, for example, a trench-first scheme, or an incomplete via-first scheme, or a buried etch stop layer scheme. The etching techniques may utilize multiple steps. For example, a first main etch step may remove a portion of the dielectric material of IMD layer 55A and stop on an etch stop dielectric layer. Then, the etchants may be switched to remove the etch stop layer dielectric materials. The parameters of the various etch steps (e.g., chemical composition, flow rate, and pressure of the gases, reactor power, etc.) may be tuned to produce tapered sidewall profiles with a desired interior taper angle.

Several conductive materials may be deposited to fill the holes and trenches forming the conductive features 53A and 54A of the first interconnect level 50A. The openings may be first lined with a conductive diffusion barrier material and then completely filled with a conductive fill material deposited over the conductive diffusion barrier liner. In some embodiments, a thin conductive seed layer may be deposited over the conductive diffusion barrier liner to help initiate an electrochemical plating (ECP) deposition step that completely fills the openings with a conductive fill material.

The diffusion barrier conductive liner in the vias 53A and lines 54A comprises one or more layers of TaN, Ta, TiN, Ti, Co, or the like, or combinations thereof. The conductive fill layer in the vias 53A and lines 54A may comprise metals such as Al, W, Pt, Ti, TiN, Ta, Ni, Cu, Ru, or the like, or combinations thereof, or multi-layers thereof. The conductive materials used in forming the conductive features 53A and 54A may be deposited by any suitable method, for example, CVD, PECVD, PVD, ALD, PEALD, ECP, electroless plating and the like. In some embodiments, the conductive seed layer may be of the same conductive material as the conductive fill layer and deposited using a suitable deposition technique (e.g., CVD, PECVD, ALD, PEALD, or PVD, or the like). Any excess conductive material over the IMD 55A outside of the openings may be removed by selective etch back. This step embeds the conductive vias 53A and conductive lines 54A into IMD 55A, as illustrated in FIG. 3B. By utilizing selective etching to remove excess conductive material over the IMD 55A, it is possible to substantially avoid or minimize physical or chemical damage to the raised semiconductor pillars 103, which may otherwise occur during alternative planarization processes, such as chemical mechanical polishing (CMP).

The interconnect level positioned vertically above the first interconnect level 50A in FIG. 3B, is the second interconnect level 50B. In some embodiments, the structures of the various interconnect levels (e.g., the first interconnect level 50A and the second interconnect level 50B) may be similar. In the example illustrated in FIG. 3B, the second interconnect level 50B comprises conductive vias 53B and conductive lines 54B embedded in an insulating film IMD 55B having a substantially planar top surface. The materials and processing techniques described above in the context of the first interconnect level 50A may be used to form the second interconnect level 50B and subsequent interconnect levels.

Although an example electronic device (FinFET 504) and example interconnect structures making connections to the electronic device are described, it is understood that one of ordinary skill in the art will appreciate that the above examples are provided for illustrative purposes only to further explain applications of the present embodiments, and are not meant to limit the present embodiments in any manner.

An ILD layer 104 is formed over the lower-level circuit structure 500 using, for example, PVD, CVD, ALD or the like. The ILD layer 104 will be planarized to expose the raised semiconductor pillars 103 that will serve as single-crystalline seeds for crystallization of a non-single crystalline semiconductor material, which will be discussed in greater detail below. Therefore, the ILD layer 104 plays a different role than the underlying IMD layers 55A, 55B and ILD layers 516, 522, and thus may have a different thickness and/or material than the IMD layers 55A, 55B and ILD layers 516, 522. For example, the ILD layer 104 may be thicker or thinner than one or more of the IMD layers 55A, 55B and ILD layers 516, 522. Alternatively, the ILD layer 104 may have a same thickness and/or material as one or more of the IMD layers 55A, 55B and ILD layers 516, 522. In some embodiments the ILD layer 104 has a maximal height measured from a bottom surface of the ILD layer 104 to a topmost position of the ILD layer 104, and the maximal height is greater than or equal to 100 nm. In certain embodiments, the raised semiconductor pillars 103 may be omitted when the semiconductor pillars 101 are formed with sufficient height such that their top surfaces extend above the top surface of the lower-level circuit structure 500.

In some embodiments, the ILD layer 104 may be made of silicon oxide (SiO₂). In some embodiments, may be made of, for example, phosphosilicate glass (PSG), borophosphosilicate glass (BPSG), fluorosilicate glass (FSG), SiOₓC_{y}, Spin-On-Glass, Spin-On-Polymers, silicon oxynitride, combinations thereof, or the like, formed by any suitable method, such as spin-on coating, chemical vapor deposition (CVD), plasma-enhanced CVD (PECVD), or the like.

Because the ILD layer 104 is deposited over an underlying surface that is inherently non-planar (e.g.,, a surface where the top surfaces of the raised semiconductor pillars 103 extend above the top surface of the lower-level circuit structure 500), the as-deposited ILD layer 104 correspondingly exhibits a non-uniform or uneven topography. In particular, the ILD layer 104 forms raised portions 104r directly above the respective raised semiconductor pillars 103, while other portions of the ILD layer 104 deposited above the lower-level circuit structure 500 are relatively recessed.

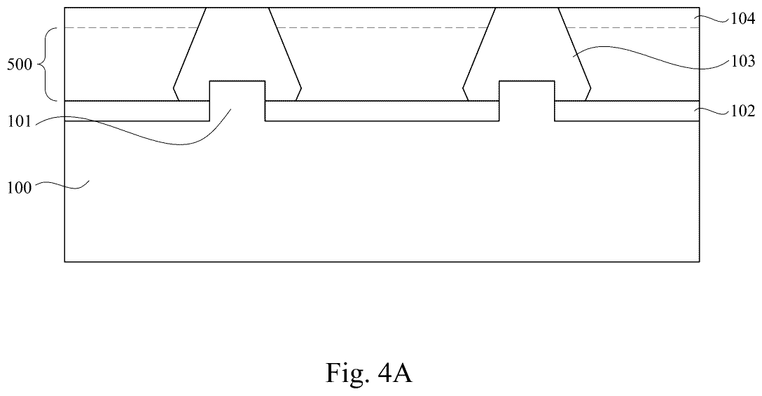

As illustrated in FIGS. 4A-4B, a chemical mechanical polishing (CMP) process is subsequently performed on the ILD layer 104. The CMP process involves both mechanical abrasion and chemical etching to remove the elevated portions of the ILD layer 104, including the raised portions 104r situated above the raised semiconductor pillars 103. Through careful control of the CMP process parameters, the top surface of the ILD layer 104 is rendered substantially planar. This planarization not only facilitates improved surface planarity for subsequent fabrication steps but also allows that the top horizontal facets 1031 of the raised semiconductor pillars 103 are exposed at the planarized surface of the ILD layer 104. Upon completion of the CMP process, a total height of a combination of a semiconductor pillar 101 and a raised semiconductor pillar 103 is substantially the same as a total height of a combination of STI region 102, ILD layers 516, 522, IMD layers 55A, 55B, and the ILD layer 104. Moreover, the height of the semiconductor pillar 101 is substantially the same as the height of the semiconductor fin 101′.

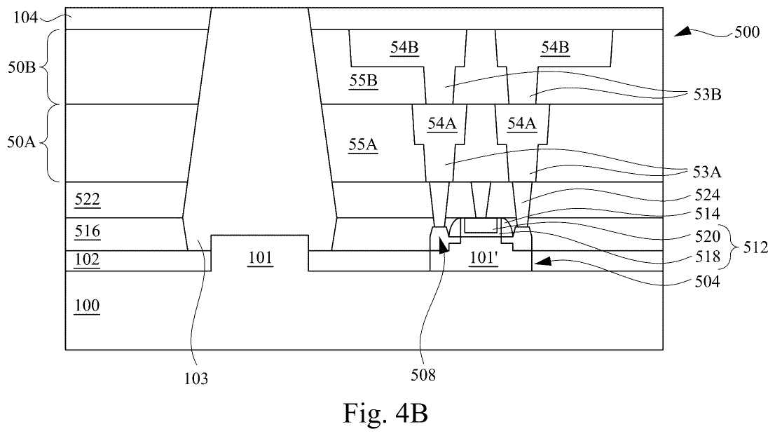

In FIG. 5, a semiconductor layer 105 is formed over the ILD layer 104 using suitable deposition techniques. The deposited semiconductor layer 105 is non-single crystalline, and is amorphous and/or polycrystalline. The semiconductor layer 105 includes silicon (Si), germanium (Ge), silicon germanium (SiₓGe₁₋ₓ), tin (Sn), germanium tin (GeₓSn₁₋ₓ), silicon germanium tin (SiₓGe_{y}Sn_{1-x-y}), III-V compound, or other semiconductor materials. In some embodiments where the semiconductor layer 105 is silicon, the silicon layer may be deposited by using silicon-containing gases (e.g., SiH₄, Si₂H₆, Si₃H₈) as precursor gases. The silicon layer may be deposited, for example, at a flow rate of the silicon-containing gas in the range from about 1000 standard cubic centimeters per minute (sccm) to about 2000 sccm, at a temperature in a rage from about 350 degrees Centigrade to about 600 degrees Centigrade, at a pressure in a range from about 400 mTorr to about 1 Torr. These process conditions for forming the silicon layer 105 is intended to be illustrative and is not intended to be limiting to embodiments of the present disclosure. Rather, any suitable processes and associated process conditions may be used. Silicon atoms and/or germanium atoms of the semiconductor layer 105 deposited on the ILD layer 104 tend to form an amorphous solid (i.e., non-crystalline solid) that lacks the long-range order of a crystal, because the dielectric material of the ILD layer 104 is amorphous in nature.

In some embodiments, a capping layer 106 is deposited over the non-single crystalline semiconductor layer 105. The capping layer 106 can serve to reduce heat dissipation rate from top surface of the non-single crystalline semiconductor layer 105 in the cooling down stage of the subsequently performed crystallization process, which in turn aids in initiating nucleation of single-crystalline semiconductor material from the bottom surface of the non-single crystalline semiconductor layer 105, which interfaces the raised semiconductor pillars 103. In some embodiments, the capping layer 106 has a thickness less than about 5 μm. In some embodiments, the capping layer 106 includes Si₃N₄, SiNₓ, SiO₂, SiOₓ, SiON, SiCN, SiOCN, or combinations thereof.

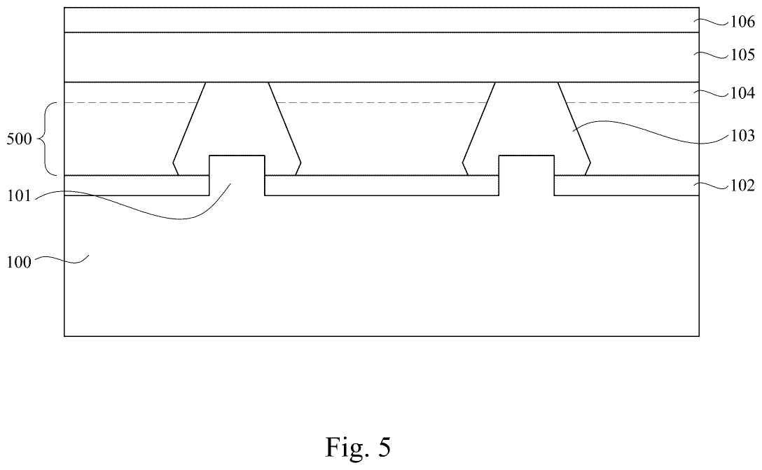

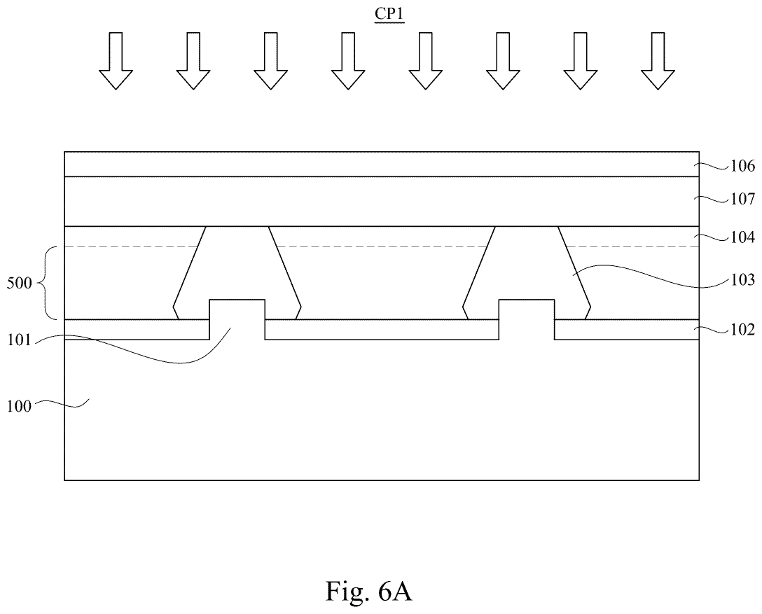

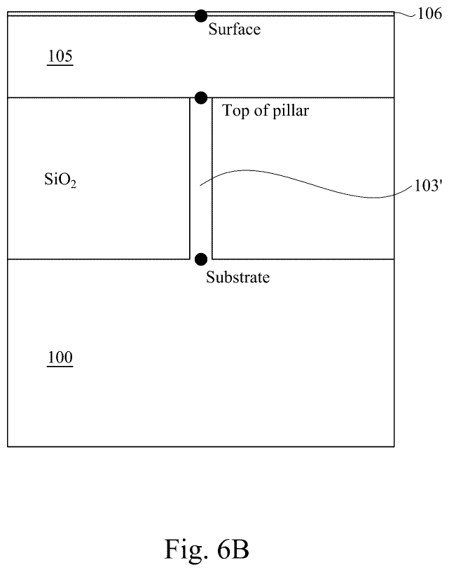

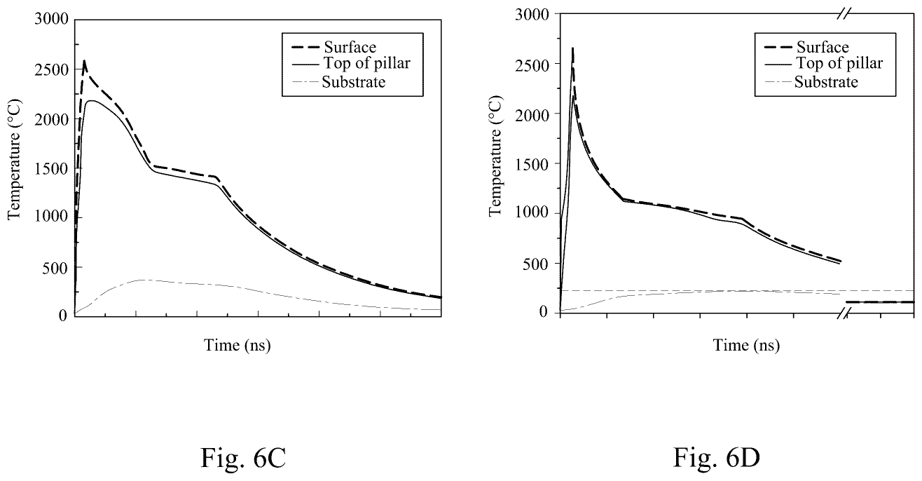

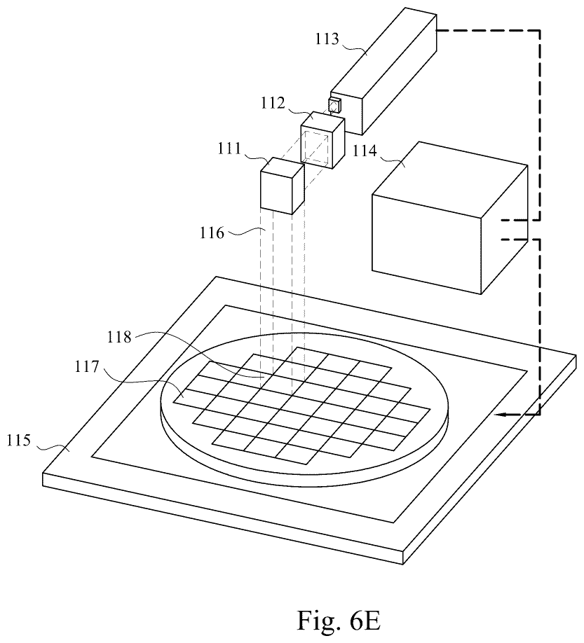

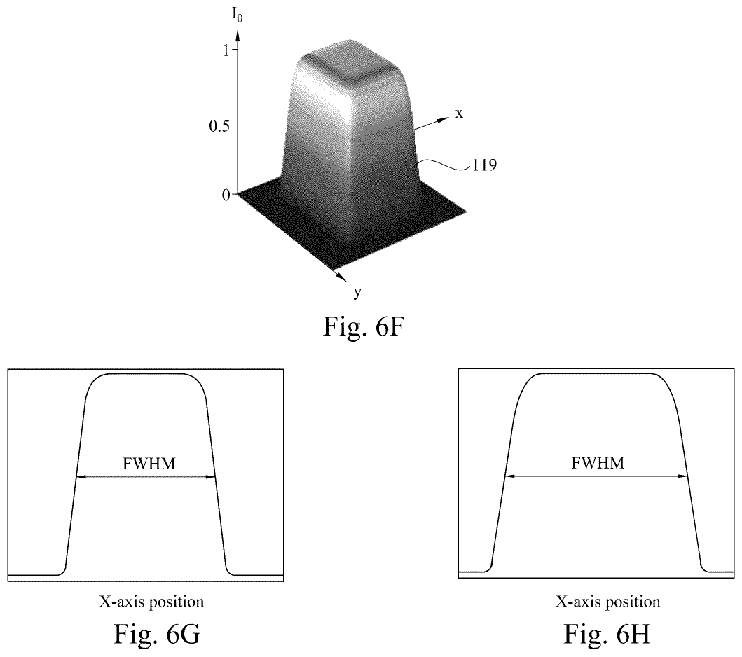

In FIG. 6A, a crystallization process CP1 is performed to convert the non-single crystalline semiconductor layer 105 into a single-crystalline semiconductor layer 107. In some embodiments, crystallization of the non-single crystalline semiconductor layer 105 can be performed using, for example, a laser anneal, a rapid thermal anneal (RTA), a millisecond anneal (mSA), the like or combinations thereof, which raises temperature to a peak temperature higher than deposition temperature of the non-single crystalline semiconductor layer 105. In greater detail, the non-single crystalline semiconductor layer 105 can heated to a peak temperature higher than a melting point of the non-single crystalline semiconductor layer 105 to melt the non-single crystalline semiconductor layer 105 into a molten state, and then the molten amorphous semiconductor will be crystallized upon cooling. Because crystallization of the molten amorphous semiconductor takes place using the underlying single-crystalline raised semiconductor pillars 103 as seeds, the resultant crystallized semiconductor layer 107 will be single-crystalline instead of polycrystalline, and thus can be referred to as a single-crystalline semiconductor layer 107.

Example crystallization process CP1 of the non-single crystalline semiconductor layer 105 is performed by the laser anneal. The laser may be pulsed laser or a continuous wave laser that is directed toward a top surface of the non-single crystalline semiconductor layer 105. Because the non-single crystalline semiconductor layer 105 is raised above the lower-level circuit structure 500 by significantly tall semiconductor pillars 103, the non-single crystalline semiconductor layer 105 can be spaced apart from the lower-level circuit structure 500 by a distance that is long enough to create a significant temperature difference between the non-single crystalline semiconductor layer 105 and the lower-level circuit structure 500 during the laser anneal, which in turn allows for melting the non-single crystalline semiconductor layer 105 while not melting materials in the lower-level circuit structure 500 (e.g., single-crystalline semiconductor materials of FinFETs 504 as illustrated in FIG. 3B). As a result, the lower-level circuit structure 500 will not be damaged by the peak temperature of the laser anneal.

In the laser anneal step of the crystallization process CP1, the non-single crystalline semiconductor layer 105 may be in its completely or substantially molten state from its top surface to its bottom surface. In some embodiments, top portions of the raised semiconductor pillars 103 may also be unintentionally molten in order to completely melt the amorphous semiconductor layer 105. Once the laser anneal stops, the molten amorphous semiconductor cools down and thus starts to crystallize into the single-crystalline layer 107. During cooling down, a heat dissipation rate of the molten semiconductor layer 105 decreases as a distance from the underlying lower-level circuit structure 500 increases, because the lower-level circuit structure 500 include multiple layers of metal lines and vias that dissipate heat at a faster rate than ambient gases, and because heat dissipation from the top surface of the molten semiconductor is further reduced by the capping layer 106. The heat dissipation rate difference thus results in a lower temperature at the bottom surface of the molten semiconductor than at the top surface of the molten semiconductor, which in turn initiates nucleation of single-crystalline semiconductor material almost only at the raised semiconductor pillars 103. Because the nucleation of semiconductor material begins from the single-crystalline raised semiconductor pillars 103, the single-crystalline raised semiconductor pillars 103 provide nucleation cites so that after cooling down the resultant semiconductor material becomes a single-crystalline semiconductor layer 107 continuous extending across the substrate 100.

FIGS. 6B, 6C, and 6D illustrate example experiment results of laser anneal. In FIG. 6B, the laser anneal is performed on a sample, which includes a substrate 100, a silicon pillar 103′ protruding from the substrate 100 and having a height of about 400 nm and a width of about 50 nm, a silicon oxide layer over the silicon substrate and having a thickness of about 400 nm, and a non-single crystalline semiconductor layer 105 formed over the silicon oxide layer. FIG. 6C illustrates temperature curves of various vertical positions of a first sample after initiating the laser anneal. In the first sample, the non-single crystalline semiconductor layer 105 is amorphous silicon. Temperature is shown on the vertical axis of FIG. 6C, and time after initiating laser anneal is shown on the horizontal axis of FIG. 6C. As illustrated in the experiment result of the laser anneal, peak temperature at the top of silicon pillar 103′ (denoted as “Top of pillar” in FIGS. 6B and 6C) is higher than 2000 degrees Centigrade (i.e., higher than melting point of amorphous silicon), and peak temperatures of higher positions (e.g., topmost position of the semiconductor layer 105 denoted as “Surface”) above the top of pillar are all higher than the peak temperature at the top of pillar and thus higher than melting point of silicon. As a result, the laser anneal can completely melt the amorphous silicon layer. On the other hand, peak temperature at the bottom of pillar (denoted as “Substrate”) is about 359 degrees Centigrade, which is lower than melting point of silicon. As a result, the laser anneal does not melt fins and source/drain epitaxy structures formed adjacent to the substrate surface.

FIG. 6D illustrates temperature curves of various vertical positions of a second sample after initiating the laser anneal. In the second sample, the non-single crystalline semiconductor layer 105 is amorphous germanium. Temperature is shown on the vertical axis of FIG. 6D, and time after initiating laser anneal is shown on the horizontal axis of FIG. 6D. As illustrated in the experiment result of the laser anneal, peak temperature at the top of silicon pillar 103′ (denoted as “Top of pillar” in FIGS. 6B and 6D) is higher than 2000 degrees Centigrade (i.e., higher than melting point of amorphous germanium), and peak temperatures of higher positions (e.g., topmost position of the semiconductor layer 105 denoted as “Surface”) above the top of pillar are all higher than the peak temperature at the top of pillar and thus higher than melting point of amorphous germanium. As a result, the laser anneal can completely melt the amorphous germanium layer. On the other hand, peak temperature at the bottom of pillar (denoted as “Substrate”) is about 214 degrees Centigrade, which is lower than melting point of germanium. As a result, the laser anneal does not melt fins and source/drain epitaxy structures formed adjacent to the substrate surface.

The experimental results illustrated in FIGS. 6B-6D show that the semiconductor pillar enables selective melting of an amorphous semiconductor material disposed above the pillar, while maintaining the solid state of the materials forming transistors in the lower-level circuit structure, as these material remain below their respective melting points during the laser anneal process.

FIG. 6E illustrates an example configuration of a flat-top laser generator suitable for use in laser anneal processes that achieves the experimental results illustrated in FIGS. 6B-6D. As shown in FIG. 6E, the flat-top laser generator comprises a laser source 113, which may be, for example, a 532 nm green nanosecond (GNS) laser, configured to generate a laser beam. A beam expander 112 is optically downstream of the laser source 113, and thus the output of the laser source 113 is directed to the beam expander 112. The beam expander 112 expands the incoming laser beam from the laser source 113, and thus outputs an expanded laser beam with an increased cross-sectional area to facilitate uniform irradiation over an enlarged target region.

Subsequently, the expanded laser beam passes through one or more optical devices 111 that are optically downstream of the beam expander 112. In some embodiments, the optical devices 111 comprise one or more lenses and/or mirrors configured to shape, focus, and direct the expanded laser beam, thereby forming a flat-top laser beam 116 that is projected onto an irradiated region 118 of a die region 117 on a wafer. The wafer is held in place on a translation stage 115. The optical devices 111 are configured to produce a flat-top (uniform intensity) beam profile in the laser beam 116, thereby allowing consistent energy delivery across the irradiated region 118. In certain embodiments, the irradiated region 118 has an area of 1 mm×1 mm, or even 1 cm×1 cm, for example, 2.6 cm×3.3 cm or 3 cm×3 cm.

The controller 114 is configured to regulate and synchronize the operation of the laser source 113 and the translation stage 115. Specifically, the controller 114 is adapted to modulate one or more output parameters of the laser source 113, such as pulse duration, output energy, and repetition rate. Additionally, the controller 114 is configured to control the movement of the translation stage 115, thereby positioning various die regions 117 so as to sequentially align a selected die region 117 with the irradiated region 118 at predetermined intervals. In certain embodiments, the controller 114 is configured to control the laser source 113 such that the laser pulse width is greater than or equal to 1 picosecond, for example, 13 nanoseconds or continuous wave (CW) operation. In some embodiments, the controller 114 is configured to control the laser source 113 such that the repetition rate of the laser is greater than or equal to 1 Hz, or the laser operates in a single pulse (single shot) mode.

During operation, the laser beam 116 is incident on a selected region of the die region 117, inducing localized heating and enabling processes such as melting and crystallization of semiconductor materials. The irradiated region 118, as indicated in FIG. 6E, corresponds to the area subjected to laser irradiation and subsequent melting and crystallization. The translation stage 115 enables controlled movement of die regions 117 relative to the incident laser beam 116, thereby allowing for selective and uniform treatment of multiple die regions 117.

In some embodiments, the irradiated region 118 is configured to have substantially the same area as the die region 117, thereby enabling implementation of a die-by-die laser anneal process. In such configurations, the laser beam profile is tailored, using beam shaping optical devices 111 and beam expander 112, to match the top-view dimensions of an individual die region 117 on the wafer. During operation, the translation stage 115 positions each die region 117 sequentially beneath the flat-top laser beam 116, such that the entire surface area of a single die region 117 is irradiated and annealed in a single exposure to the laser beam 116. This approach allows for precise thermal processing of each die region 117, minimizing thermal gradients and edge effects that may otherwise arise in partial or overlapping irradiation schemes, which in turn reduces the risk of non-uniform crystallization. The die-by-die laser anneal process thus supports a high-throughput, repeatable, and uniform crystallization process CP1. In some embodiments, the irradiated region 118 is configured to have an area that is a multiple of the area of a single die region 117, thereby enabling simultaneous crystallization of a plurality of die regions 117. In some embodiments, a number of the laser source 113 may be greater than or equal to 1.

FIG. 6F illustrates a three-dimensional representation of an intensity profile of a laser beam 119 generated by the flat-top laser generator as illustrated in FIG. 6E. The laser beam exhibits a super-Gaussian or flat-top intensity distribution, which has a substantially uniform intensity across the central region of the beam profile in both the x and y directions, with relatively steep intensity gradients at the periphery. This beam profile is particularly advantageous for achieving uniform thermal processing across the irradiated region of an amorphous semiconductor material, thereby reducing non-uniformities in the laser anneal process.

FIG. 6G illustrates a cross-sectional intensity profile of the laser beam 119 along the x-axis, corresponding to the horizontal direction of the irradiated region in a top view. The profile shows a flat-top shape with a full width at half maximum (FWHM) of approximately 26 mm, indicating the width of the region over which the beam intensity remains above half of its maximum value. This dimension may be selected to match the desired anneal size, such as a die width of the die region 117 to be annealed.

FIG. 6H illustrates a cross-sectional intensity profile of the laser beam 119 along the y-axis, corresponding to the vertical direction of the irradiated region in a top view. The profile similarly exhibits a flat-top shape with a FWHM of approximately 33 mm, indicating the length of the region over which the beam intensity remains above half of its maximum value. This parameter may be selected to match the desired anneal size, such as a die length of the die region 117 to be annealed.

Collectively, FIGS. 6F, 6G, and 6H show that the laser beam generated by the apparatus of FIG. 6E possesses a substantially uniform (flat-top or super-Gaussian) intensity profile with well-defined dimensions in both the x and y directions. Such a beam profile enables precise and uniform melting of semiconductor materials across a defined region (e.g., a single die region).

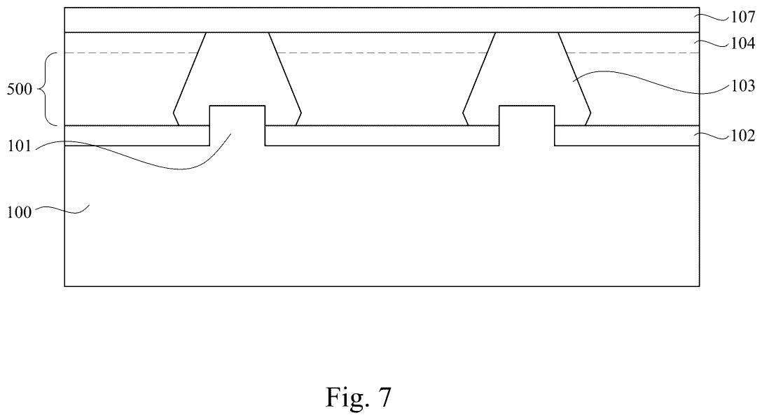

After formation of the single-crystalline semiconductor layer 107, a CMP process is performed to remove the capping layer 106. The resulting structure is illustrated in FIG. 7. In certain embodiments, the CMP process not only removes the capping layer 106 but also reduces the thickness of the single-crystalline semiconductor layer 107 from an initial value to a final value that is less than the initial value. This thinning step is advantageous, as it enables the resultant semiconductor layer 107 to achieve a thickness that is more suitable for serving as semiconductor channels in subsequent device fabrication processes.

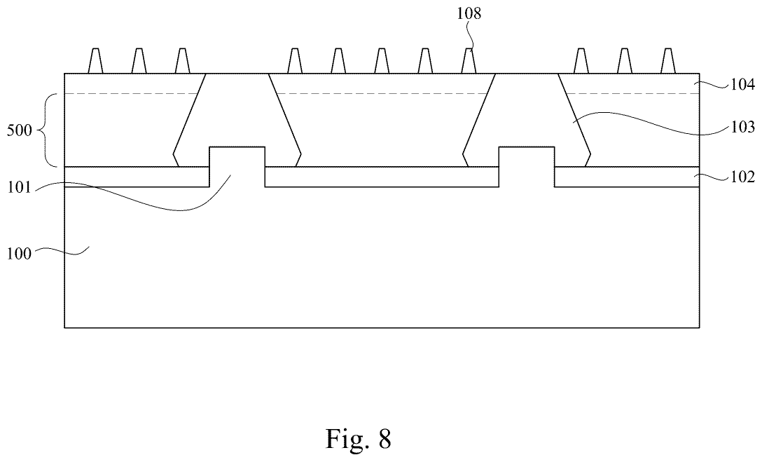

In FIG. 8, a plurality of single-crystalline semiconductor fins 108 are formed on the ILD layer 104 by patterning the single-crystalline semiconductor layer 107 by using suitable photolithography and etching techniques. For example, a photoresist (not shown) may be formed over the single-crystalline semiconductor layer 107 using a spin-on coating process, followed by patterning the photoresist to forming a plurality of holes using suitable photolithography techniques, and then the single-crystalline layer 107 is etched using the patterned photoresist as an etch mask until the ILD layer 104 and the raised semiconductor pillars 103 are exposed, thus resulting in single-crystalline semiconductor fins 108 protruding above the top surface of the ILD layer 104. In the illustrated embodiment of FIG. 8, the top horizontal facets of the raised semiconductor pillars 103 are offset from the single-crystalline semiconductor fins 108. However, in some other embodiments, the top horizontal facets of the raised semiconductor pillars 103 may overlap with the single-crystalline semiconductor fins 108. Because the fins 108 are formed above the lower-level circuit structure 500, these fins 108 can be interchangeably referred to as upper-level fins 108 that are disposed above the fins in the lower-level circuit structure 500.

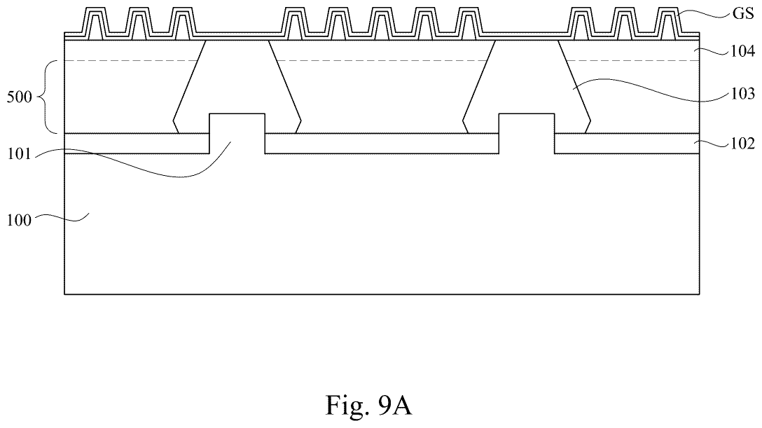

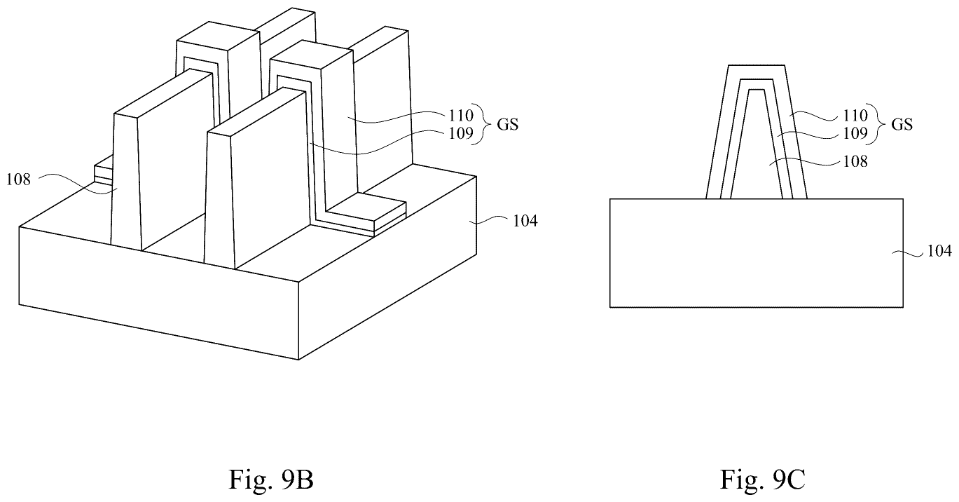

In FIGS. 9A-9C, a gate dielectric layer 109 is formed over the upper-level fins 108 by using suitable deposition techniques, such as CVD, plasma-enhanced CVD (PECVD), atomic layer deposition (ALD), plasma-enhanced ALD (PEALD) or the like, or by thermal oxidation of the semiconductor surface, or combinations thereof. In some embodiments, gate dielectric layer 109 includes, for example, a high-k dielectric material such as oxides and/or silicates of metals (e.g., oxides of Hf, Al, Zr, La, Mg, Ba, Ti, and other metals), silicon nitride, silicon oxide, and the like, or combinations thereof, or multilayers thereof. For example, the gate dielectric layer 109 includes Al₂O₃, AlₓO₁₋ₓ, HfO₂, HfₓO₁₋ₓ, ZrO₂, ZrₓO₁₋ₓ, HZO, Ta₂O₅, TaₓO₁₋ₓ, TiO₂, TiₓO₁₋ₓ, Y₂O₃, YₓO₁₋ₓ, CeO₂, CeₓO₁₋ₓ, BaTiO₃, BaₓTi_{y}O_{1-x-y}.

A gate metal layer 110 is formed over the gate dielectric layer 109 by using any suitable method, e.g., CVD, PECVD, physical vapor deposition (PVD), ALD, PEALD, electrochemical plating (ECP), electroless plating and/or the like. In some embodiments, the gate metal layer 110 may be a multilayered metal gate stack comprising a barrier layer, a work function layer, and a top metal layer formed successively on top of gate dielectric layer 109. Example materials for a barrier layer include TiN, TaN, Ti, Ta, or the like, or a multilayered combination thereof. A work function layer may include TiN, TaN, Ru, Mo, Al, for a p-type FET, and Ti, Ag, TaAl, TaAlC, TiAlN, TaC, TaCN, TaSiN, Mn, Zr, for an n-type FET. Other suitable work function materials, or combinations, or multilayers thereof may be used. The top metal layer may comprise metals such as Cu, Al, W, Co, Ru, or the like, or combinations thereof, or multi-layers thereof.

Once deposition of the gate metal layer 110 and the gate dielectric layer 109 is completed, they will be patterned to form a high-k, metal gate (HKMG) gate structure GS extending across channel regions of the upper-level fins 108, while leaving other regions of the upper-level fins 108 exposed, as illustrated in the perspective view of FIG. 9B.

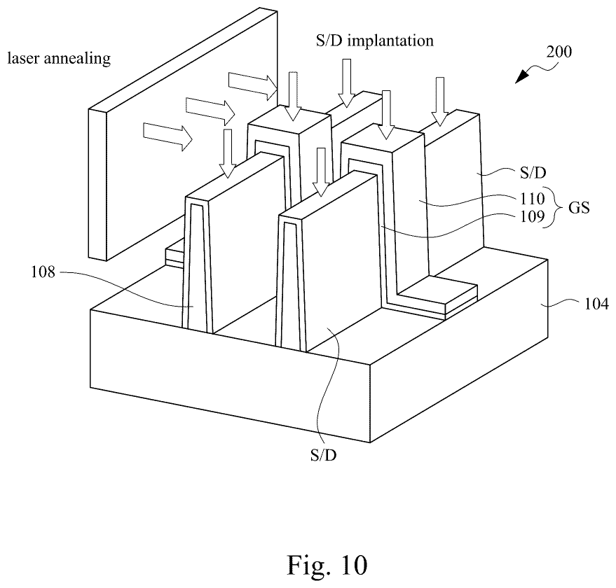

In FIG. 10, a source/drain implantation process is performed to implant n-type or p-type dopants (e.g., As, P, B, In, or the like) on the exposed regions of the upper-level fins 108, and then an anneal is performed on the implanted regions of the upper-level fins 108 to activate the implanted dopants in each implanted regions, thus forming source/drain regions S/D on opposite sides of the HKMG gate structure GS. In some embodiments, activation of the implanted dopants can be performed using, for example, a laser anneal, a rapid thermal anneal (RTA), a millisecond anneal (mSA), the like or combinations thereof. For example, a CO₂ laser may be used to activate the implanted dopants.

The upper-level fins 108, the source/drain regions S/D in the upper-level fins 108, and the gate structure GS can form upper-level FinFETs 200 on the ILD layer 104. In the illustrated embodiments, the transistors 200 are FinFETs. In some other embodiments, the transistors 200 are planar FETs, gate-all-around (GAA) FETs, nanosheet FETs, nanowire FETs, or other suitable FETs.

In the illustrated embodiment, the upper-level FinFETs 200 are formed without forming additional STI regions above the ILD layer 104. This is because the upper-level fins 108 are formed on the ILD layer 104 and thus can be insulated from each other by the ILD layer 104 without the need of additional STI regions. However, the STI-free fins 108 are intended to be illustrative and not intended to be limiting to embodiments of the present disclosure. In some other embodiments, additional STI regions may be formed around the fins 108 before forming the gate structure GS, thus improving insulation between the fins 108.

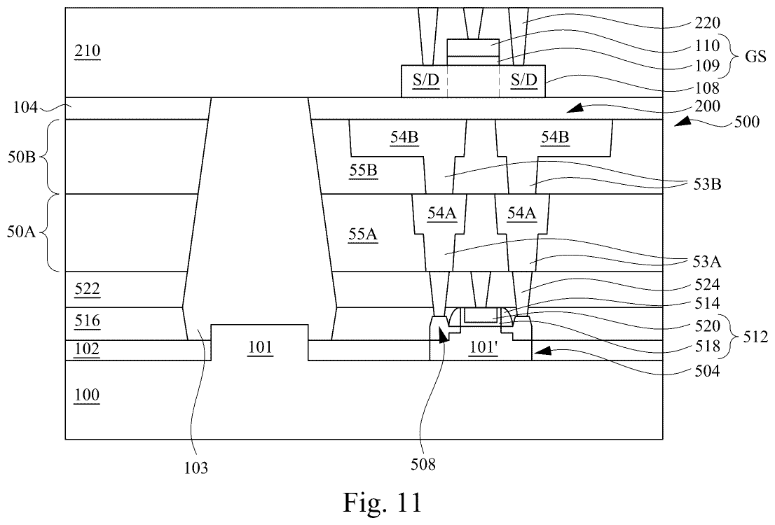

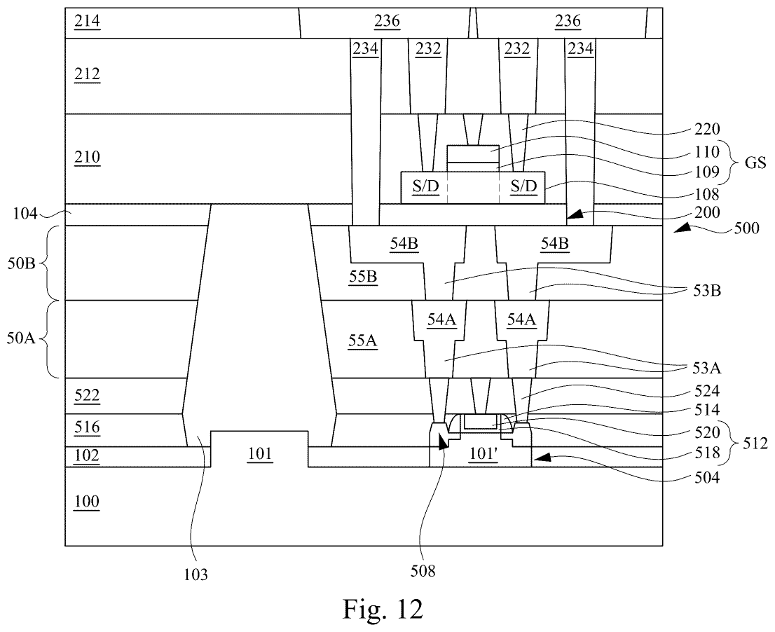

In FIG. 11, an ILD layer 210 is formed over the upper-level FinFETs 200. The ILD layer 104 may comprise silicon oxide, phosphosilicate glass (PSG), borosilicate glass (BSG), boron-doped phosphosilicate glass (BPSG), undoped silicate glass (USG), a low dielectric constant (low-k) dielectric such as, fluorosilicate glass (FSG), silicon oxycarbide (SiOCH), carbon-doped oxide (CDO), flowable oxide, or porous oxides (e.g., xerogels/aerogels), or the like, or a combination thereof. The dielectric materials used to form the first ILD layer 516 and the second ILD layer 522 may be deposited using any suitable method, such as CVD, physical vapor deposition (PVD), ALD, PEALD, PECVD, SACVD, FCVD, spin-on, and/or the like, or a combination thereof. Once the ILD layer 210 is formed, contacts 220 are formed in the ILD layer 210 to land on the gate structures GS and source/drain regions S/D, respectively. In the embodiment illustrated in FIG. 11, some contacts 220 make electrical connections to the source and drain regions S/D of upper-level FinFETs 200 and can be referred to as upper-level source/drain contacts, some contacts 220 make electrical connections to gate structures GS of upper-level FinFETs 200 and can be referred to as gate contacts. The contacts 220 may be formed using similar processes and materials as discussed previously with respect to the lower-level contacts 524.

After forming the contacts 220, another multilevel interconnect structure is formed over the contacts 220 using similar processes and materials as discussed previously with respect to the multilevel interconnect structure 50A and 50B. For example, as illustrated in FIG. 12, an IMD layer 212 is formed over the ILD layer 210 and the contacts 220 by using suitable deposition techniques, followed by forming vias 232 and 234 in the IMD layer 212. In some embodiments, the vias 232 extend from the top surface of the IMD layer 212 to the top surfaces of the contacts 220, and the vias 234 extend a greater height from the top surface of the IMD layer 212 to the conductive lines 54B in the lower-level circuit structure 500. Next, another IMD layer 214 is formed over the IMD layer 212 by using suitable deposition techniques, followed by forming conductive lines 236 laterally extending lengthwise in the IMD layer 214. In some embodiments, a conductive line 236 extends across the conductive vias 232, 234, and thus electrically connects a source/drain region S/D of the upper-level transistor 200 to the lower-level circuit structure 500. In some embodiments, the conductive vias 232, 234, and conductive lines 236 comprise one or more layers of TaN, Ta, TiN, Ti, Co, Al, W, Pt, Ni, Cu, Ru, or the like.

The upper-level transistors 200 above the interconnect structure 50A, 50B and the transistors 504 below the interconnect structure 50A, 50B can form an integrated circuit (IC). Because the IC includes transistors at different levels (e.g., transistors 200 at a higher level than transistors 504), it can be referred to as a three dimensional (3D) IC structure.

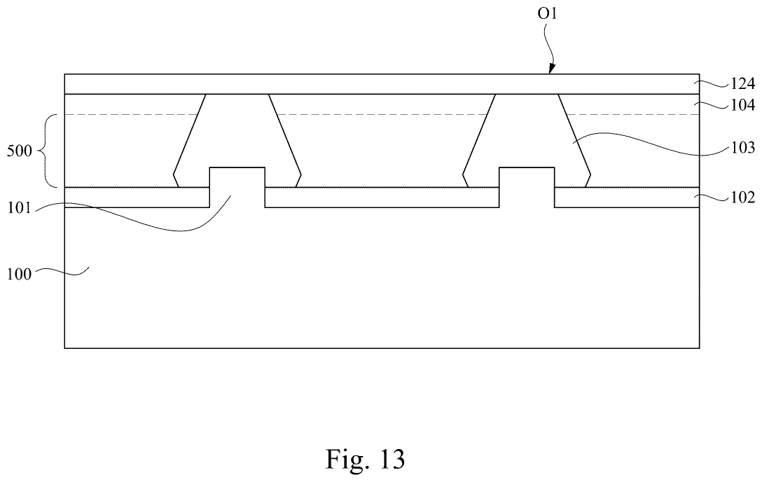

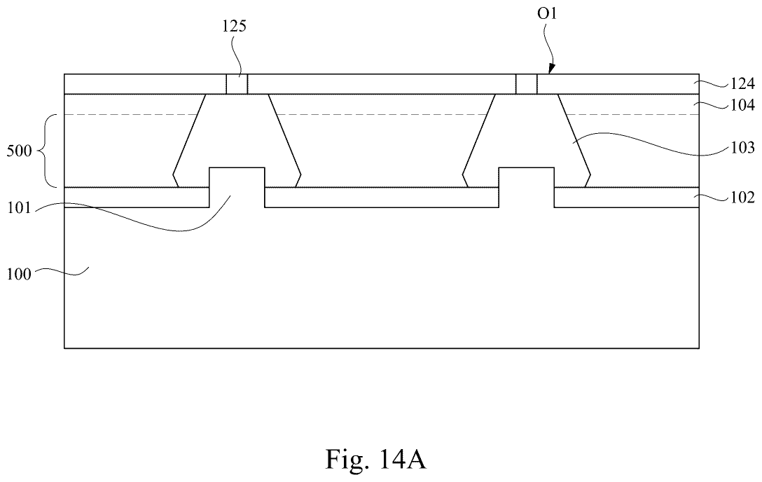

FIGS. 13-22 illustrate intermediate stages of a method of forming a 3D IC structure in accordance with some embodiments. Although the cross-sectional views shown in FIGS. 13-22 are described with reference to a method, it will be appreciated that the structures shown in FIGS. 13-22 are not limited to the method but rather may stand alone separate of the method. Although FIGS. 13-22 are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

FIG. 13 is cross-sectional views of an example initial structure comprising a semiconductor substrate 100, semiconductor pillars 101 formed over the substrate 100, raised semiconductor pillars 103 formed over the semiconductor pillars 101, STI regions 102 formed around lower portions of the semiconductor pillars 101, and a lower-level circuit structure 500 formed over the semiconductor substrate 100. FIG. 13 shows substantially the same structure as FIG. 4A, except for an additional dielectric layer 124 formed over the ILD layer 104 and the raised semiconductor pillars 103. In some embodiments, the dielectric layer 124 has a dielectric constant greater than a dielectric constant of the ILD layer 104. For example, when the ILD layer 104 is a silicon oxide (SiO₂) layer, the dielectric layer 124 may be a silicon nitride (SiNₓ) layer having a greater dielectric constant than silicon oxide. In some other embodiments, the dielectric layer 124 includes Al₂O₃, AlₓO₁₋ₓ, HfO₂, HfₓO₁₋ₓ, ZrO₂, ZrₓO₁₋ₓ, La₂O₃, LaₓO₁₋ₓ, Si₃N₄. The dielectric layer 124 can reduce the risk of leakage current from the subsequently formed upper-level devices to the lower-level circuit structure 500. In some embodiments, a thickness of the dielectric layer 124 is less than or equal to a thickness of the ILD layer 104. Stated differently, a ratio of the thickness of the dielectric layer 124 to thickness of the ILD layer 104 is less than or equal 1.

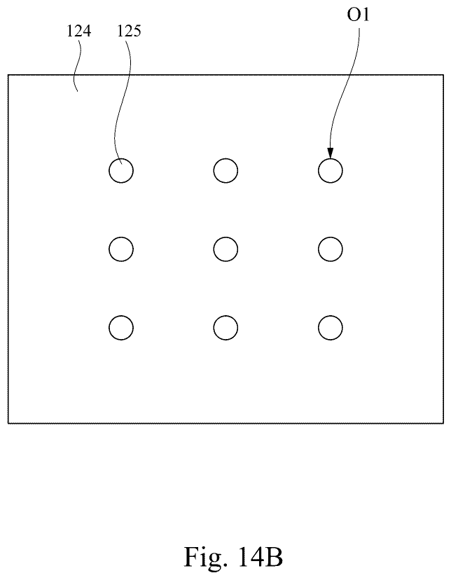

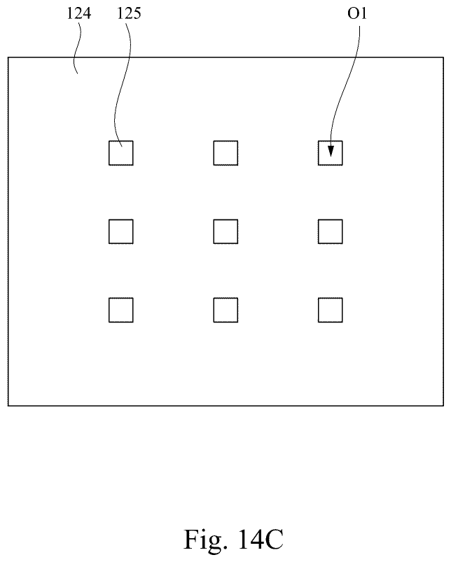

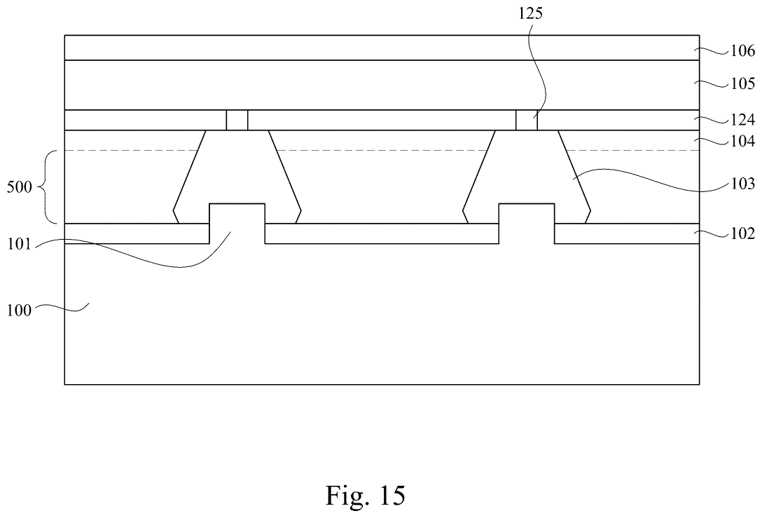

In FIG. 14A, holes O1 are etched in the dielectric layer 124 and the lower-level circuit structure 500 until the single-crystalline semiconductor pillars 103 are exposed. The holes O1 may arranged equidistantly in rows and columns, as illustrated in top views of FIGS. 14B and 14C. In some embodiments, the holes O1 are formed using suitable photolithography and etching techniques. For example, a photoresist layer is formed over the dielectric layer 124 by using a spin-on coating process, followed by patterning the photoresist layer to expose target regions of the dielectric layer 124 using suitable photolithography techniques. For example, photoresist layer is irradiated (exposed) and developed to remove portions of the photoresist layer. In greater detail, a photomask or reticle (not shown) may be placed above the photoresist layer, which may then be exposed to a radiation beam which may be ultraviolet (UV) or an excimer laser such as a Krypton Fluoride (KrF) excimer laser, or an Argon Fluoride (ArF) excimer laser. Exposure of the photoresist material may be performed, for example, using an immersion lithography tool or an extreme ultraviolet light (EUV) tool to increase resolution and decrease the minimum achievable pitch. A bake or cure operation may be performed to harden the exposed photoresist layer, and a developer may be used to remove either the exposed or unexposed portions of the photoresist material depending on whether a positive or negative resist is used. After the patterned photoresist layer is formed, an etching process is performed on the exposed target regions of the dielectric layer 124, thus forming holes O1 in the dielectric layer 124. Although the holes O1 illustrated in FIG. 14A have vertical sidewalls, the etching process may lead to tapered sidewalls, in some other embodiments.

Although the holes O1 depicted in FIG. 14B are round (or circular) holes when viewed from above, holes with other suitable shapes may also be formed in the dielectric layer 124. FIG. 14C illustrates a top view of an alternative embodiment of the holes O1 formed in the dielectric layer 124. The holes O1 may be square holes (or rectangular holes) each having four straight sidewalls. In some embodiments, a ratio of the horizontal size (e.g., width or diameter) of the hole O1 to the thickness of the dielectric layer 124 is in a range from 0.1 to 10.

Next, semiconductor plugs 125 are grown in the holes O1 in the dielectric layer 124 by using the raised semiconductor pillars 103 as seeds. In some embodiments because growth of the plugs 125 takes place using the underlying single-crystalline raised semiconductor pillars 103 as seeds, the resultant plugs 125 can be single-crystalline instead of polycrystalline, and thus can be referred to as single-crystalline semiconductor plugs 125. The single-crystalline semiconductor plugs 125 are Si, Ge, or SiGe formed using a selective low-temperature epitaxy growth at a temperature not higher than melting point of the semiconductor materials of the lower-level transistor 504. Therefore, epitaxy growth of the single-crystalline semiconductor plugs 125 has no or negligible impact on the lower-level transistor 504. Because the semiconductor plugs 125 are formed using epitaxy growth, they can be interchangeably referred to as epitaxial plugs 125. For example, in some embodiments where the semiconductor plugs 125 include silicon, the silicon plugs 125 can be formed by low-temperature epitaxy using silane (SiH₄), disilane (Si₂H₆), trisilane (Si₃H₈), or other silicon-containing precursors such as high-order silanes. The silicon-containing precursors may also contain chlorine, e.g. SiH₂Cl₂. The epitaxy growth temperature may be an elevated temperature higher than room temperature (about 21° C.). For example, the temperature may be lower than about 500 degrees Centigrade. A low growth temperature minimizes the likelihood of melting the lower-level fins 101′ and source/drain regions 508 on the lower-level fins 101′. In some embodiments, the semiconductor plugs 125 may be grown as amorphous semiconductor plugs (e.g., amorphous Si or Ge plugs), depending on the growth conditions.

Because the epitaxial plugs 125 are grown to fill the holes O1, the epitaxial plugs 125 have top-view profile and cross-sectional profile the same as the top-view profile and the cross-sectional profile of the holes O1, as illustrated in FIGS. 14A-14C. Therefore, the epitaxial plugs 125 may have vertical sidewalls or tapered sidewalls, depending on sidewall profiles of the holes, and the epitaxial plugs 125 may have a circular top-view profile as illustrated in FIG. 14B or quadrilateral top-view profile (or square top-view profile) as illustrated in FIG. 14C. In some embodiments, the top-view pattern or plan-view pattern of the epitaxial plugs 125 can be rectangular, circular, linear, L-shaped, T-shaped, or other shapes.

In FIG. 15, a semiconductor layer (e.g., amorphous semiconductor layer) 105 is formed over the dielectric layer 124 using suitable deposition techniques. The deposited semiconductor layer 105 is non-single crystalline, and is amorphous and/or polycrystalline. The semiconductor layer 105 includes silicon (Si), germanium (Ge), silicon germanium (SiGe), or other semiconductor materials. Other details about the semiconductor layer 105 are discussed previously with respect to FIG. 5, and thus they are not repeated for the sake of brevity.

In some embodiments, a capping layer 106 is deposited over the non-single crystalline semiconductor layer 105. The capping layer 106 can serve to reduce heat dissipation rate from top surface of the non-single crystalline semiconductor layer 105 in the cooling down stage of the subsequently performed crystallization process, which in turn aids in initiating nucleation of single-crystalline semiconductor material from the bottom surface of the non-single crystalline semiconductor layer 105, which interfaces the single-crystalline semiconductor plugs 125. In some embodiments the capping layer 106 has a thickness less than about 5 μm. In some embodiments, the capping layer 106 includes Si₃N₄, SiNₓ, SiO₂, SiOₓ, SiON, SiCN, SiOCN, or combinations thereof.

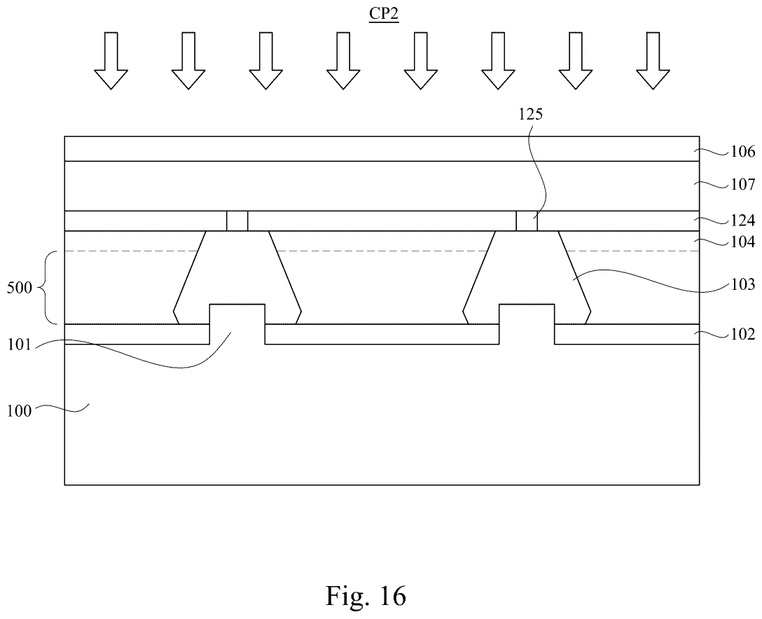

In FIG. 16, a crystallization process CP2 is performed to convert the amorphous semiconductor layer 105 into a single-crystalline semiconductor layer 107. In some embodiments, crystallization of the amorphous semiconductor layer 105 can be performed using, for example, a laser anneal, a rapid thermal anneal (RTA), a millisecond anneal (mSA), the like or combinations thereof, which raises temperature to a peak temperature higher than deposition temperature of the amorphous semiconductor layer 105. In greater detail, the amorphous semiconductor layer 105 can heated to a peak temperature higher than a melting point of the amorphous semiconductor layer 105 to melt the amorphous semiconductor layer 105 into a molten state, and then the molten amorphous semiconductor will be crystallized upon cooling. Because crystallization of the molten amorphous semiconductor takes place using the underlying single-crystalline epitaxial plugs 125 as seeds, the resultant crystallized semiconductor layer 107 will be single-crystalline instead of polycrystalline, and thus can be referred to as a single-crystalline semiconductor layer 107.

In some embodiments, the nitride material of the dielectric layer 124 can suppress spontaneous nucleation of the amorphous semiconductor layer 105 during crystallization, particularly in regions except for the single-crystalline semiconductor plugs 125. This suppression mitigates uncontrolled crystal orientation that may otherwise result from spontaneous nucleation events outside the semiconductor plugs 125. Furthermore, the nitride material of the dielectric layer 124 is more effective than the oxide material of the ILD layer 104 in inhibiting spontaneous nucleation of silicon or germanium, thereby providing enhanced control over crystal orientation during the crystallization process CP2.

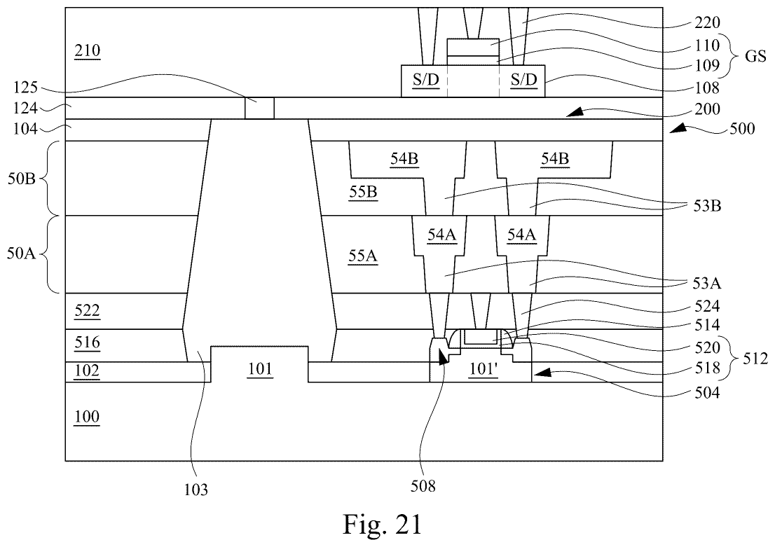

Example crystallization process CP2 of the amorphous semiconductor layer 105 is performed by the laser anneal. The laser may be pulsed laser or a continuous wave laser that is directed toward a top surface of the amorphous semiconductor layer 105. Because the amorphous semiconductor layer 105 is raised above the lower-level circuit structure 500 by a significant total height of the raised semiconductor pillars 103 and semiconductor plugs 125, the amorphous semiconductor layer 105 can be spaced apart from the lower-level circuit structure 500 by a vertical distance that is long enough to create a significant temperature difference between the amorphous semiconductor layer 105 and the lower-level circuit structure 500 during the laser anneal, which in turn allows for melting the amorphous semiconductor layer 105 while not melting materials in the lower-level circuit structure 500 (e.g., semiconductor materials of FinFETs 504 as illustrated in FIG. 21). As a result, the lower-level circuit structure 500 will not be damaged by the peak temperature of the laser anneal. In some embodiments, top portions of the epitaxial plugs 125 may also be unintentionally molten in order to completely melt the amorphous semiconductor layer 105.

Once the laser anneal process stops, the molten amorphous semiconductor cools down and starts to crystallize into the single-crystalline layer 107. During cooling down, a heat dissipation rate in the dielectric layer 124 decreases as a distance from the underlying lower-level circuit structure 500 increases, because the lower-level circuit structure 500 include multiple layers of metal lines and vias that dissipate heat at a faster rate than ambient gases. Therefore, bottoms of the holes O1 in the dielectric layer 124 have a faster heat dissipation rate than a top surface of the dielectric layer 124 during cooling down. The heat dissipation rate difference thus results in a lower temperature at bottoms of the holes O1 in the dielectric layer 124 than at the top surface of the dielectric layer 124, which in turn initiates nucleation of single-crystalline semiconductor material almost only at the bottoms of the holes O1, rather than initiating nucleation uniformly across the dielectric layer 124. In some embodiments, the molten amorphous semiconductor can be reheated before spontaneous nucleation on the dielectric layer 124 begins, which in turn can aid in initiating nucleation at the bottoms of holes O1 in the dielectric layer 124, because the spontaneous nucleation above the top surface of the dielectric layer 124 can be suppressed by the reheating. Because the nucleation of semiconductor material begins from the bottom of holes O1, the single-crystalline semiconductor plugs 125 provide nucleation cites such that after cooling down the resultant semiconductor material becomes a single-crystalline semiconductor layer 107 continuous extending across the dielectric layer 124. Other details about forming the single-crystalline semiconductor layer 107 are discussed previously with respect to FIGS. 6A-6H, and thus they are not repeated for the sake of brevity.

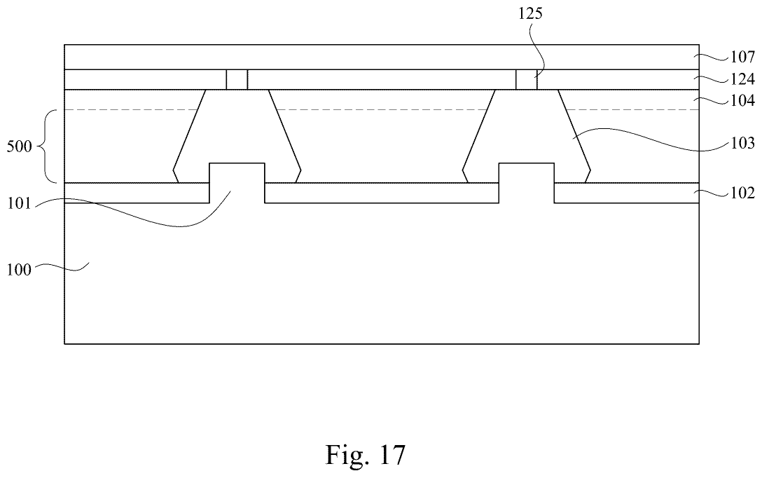

After formation of the single-crystalline semiconductor layer 107, a CMP process is performed to remove the capping layer 106. The resulting structure is illustrated in FIG. 17. In certain embodiments, the CMP process not only removes the capping layer 106 but also reduces the thickness of the single-crystalline semiconductor layer 107 from an initial value to a final value that is less than the initial value. This thinning step is advantageous, as it enables the resultant semiconductor layer 107 to achieve a thickness that is more suitable for serving as semiconductor channels in subsequent device fabrication processes.

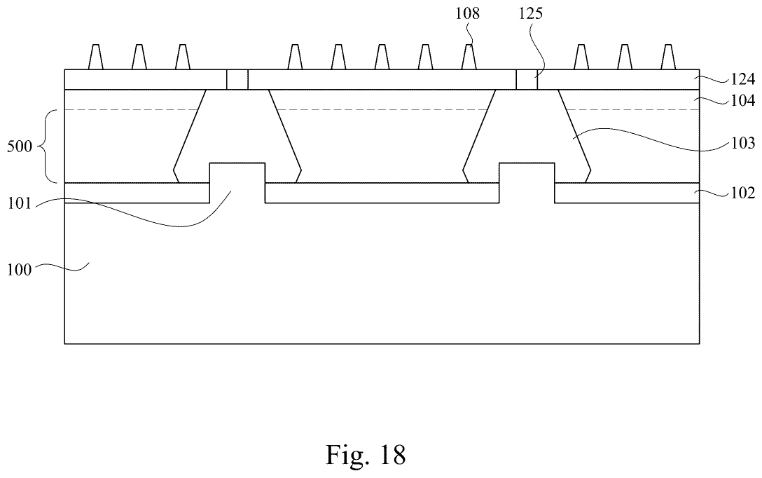

In FIG. 18, a plurality of single-crystalline semiconductor fins 108 are formed on the dielectric layer 124 by patterning the single-crystalline semiconductor layer 107 by using suitable photolithography and etching techniques. For example, a photoresist (not shown) may be formed over the single-crystalline semiconductor layer 107 using a spin-on coating process, followed by patterning the photoresist to forming a plurality of holes using suitable photolithography techniques, and then the single-crystalline layer 107 is etched using the patterned photoresist as an etch mask until the dielectric layer 124 and the epitaxial plugs 125 are exposed, thus resulting in single-crystalline semiconductor fins 108 protruding above the top surface of the dielectric layer 124. In the illustrated embodiment of FIG. 18, the epitaxial plugs 125 are offset from the single-crystalline semiconductor fins 108. However, in some other embodiments, the epitaxial plugs 125 may overlap with the single-crystalline semiconductor fins 108. Because the fins 108 are formed above the lower-level circuit structure 500, these fins 108 can be interchangeably referred to as upper-level fins 108 that are disposed above the fins in the lower-level circuit structure 500.

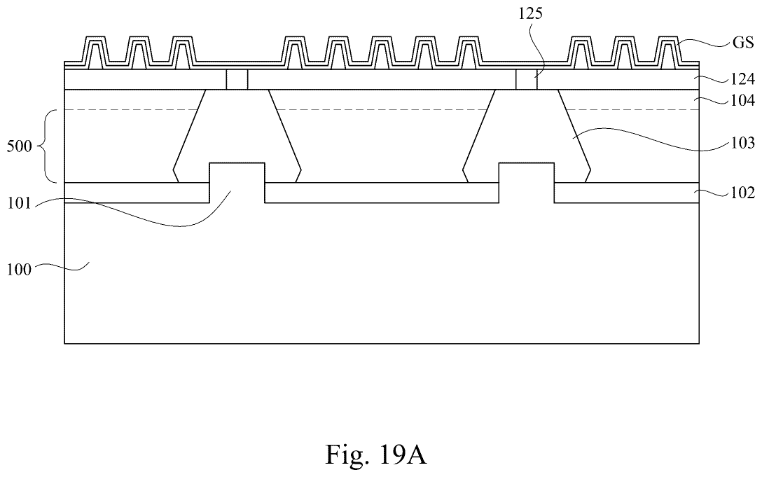

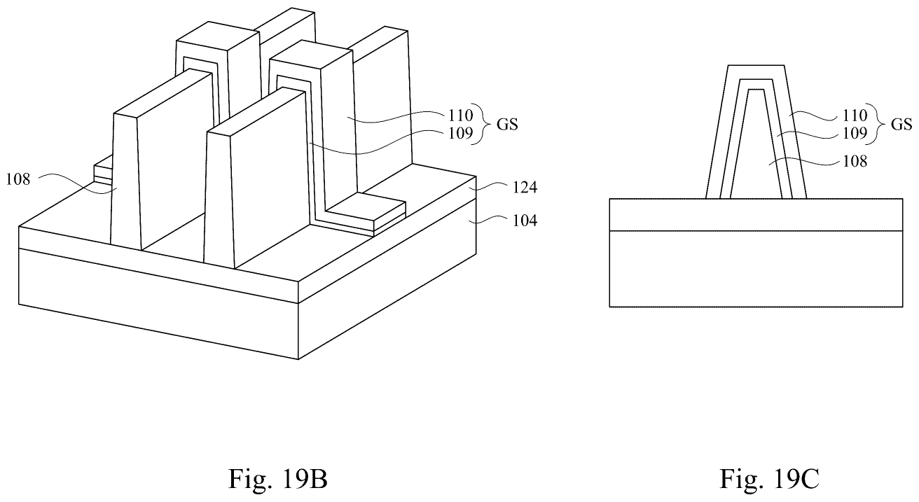

In FIGS. 19A-19C, a gate dielectric layer 109 and a gate metal layer 110 are deposited in sequence over the upper-level fins 108, followed by patterning the gate dielectric layer 109 and the gate metal layer 110 into a HKMG gate structure GS extending across channel regions of the upper-level fins 108, while leaving other regions of the upper-level fins 108 exposed, as illustrated in the perspective view of FIG. 19B. Other details about the HKMG gate structure GS are discussed previously with respect to FIGS. 9A-9C, and thus they are not repeated for the sake of brevity.

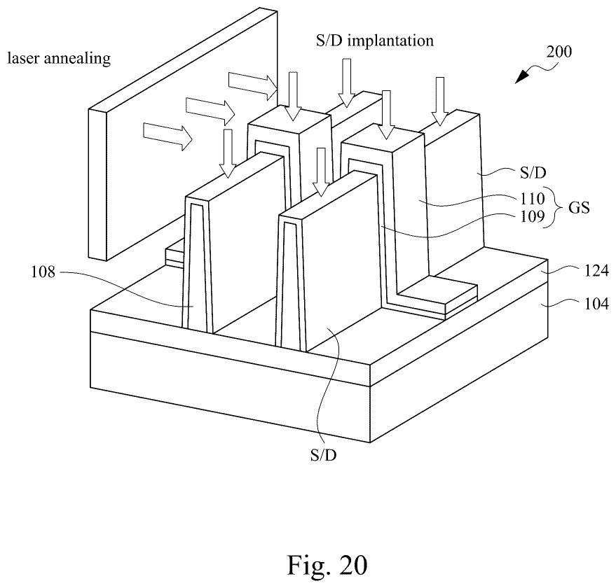

In FIG. 20, a source/drain implantation process is performed to implant n-type or p-type dopants (e.g., As, P, B, In, or the like) on the exposed regions of the upper-level fins 108, and then an anneal is performed on the implanted regions of the upper-level fins 108 to activate the implanted dopants in each implanted regions, thus forming source/drain regions S/D on opposite sides of the HKMG gate structure GS. In some embodiments, activation of the implanted dopants can be performed using, for example, a laser anneal, a rapid thermal anneal (RTA), a millisecond anneal (mSA), the like or combinations thereof. For example, a CO₂ laser may be used to activate the implanted dopants. The upper-level fins 108, the source/drain regions S/D in the upper-level fins 108, and the gate structure GS can form upper-level FinFETs 200 disposed on the dielectric layer 124. In the illustrated embodiments, the transistors 200 are FinFETs. In some other embodiments, the transistors 200 are planar FETs, gate-all-around (GAA) FETs, nanosheet FETs, nanowire FETs, or other suitable FETs.

In FIG. 21, an ILD layer 210 is formed over the upper-level FinFETs 200, and contacts 220 are formed in the ILD layer 210 to make electrical connections to the gate structures GS and source/drain regions S/D, respectively. Details about the ILD layer 210 and contacts 220 are discussed previously with respect to FIG. 11, and thus they are not repeated for the sake of brevity.

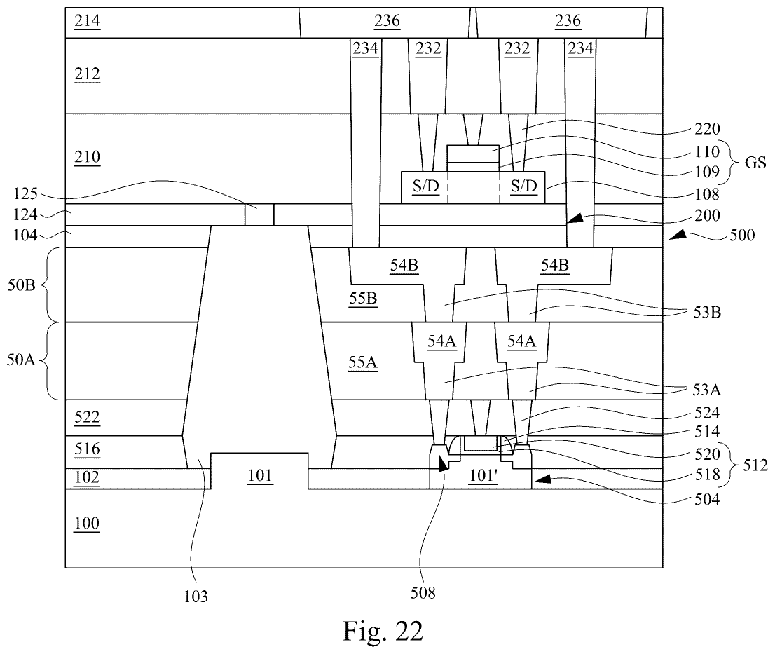

In FIG. 22, an IMD layer 212 is formed over the ILD layer 210 and the contacts 220 by using suitable deposition techniques, followed by forming vias 232 and 234 in the IMD layer 212. In some embodiments, the vias 232 extend from the top surface of the IMD layer 212 to the top surfaces of the contacts 220, and the vias 234 extend a greater height from the top surface of the IMD layer 212 to the conductive lines 54B in the lower-level circuit structure 500. Next, another IMD layer 214 is formed over the IMD layer 212 by using suitable deposition techniques, followed by forming conductive lines 236 laterally extending lengthwise in the IMD layer 214. In some embodiments, a conductive line 236 extends across the conductive vias 232, 234, and thus electrically connects a source/drain region S/D of the upper-level transistor 200 to the lower-level circuit structure 500.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that single-crystalline semiconductor can be formed above a lower-level circuit structure by crystallizing a non-single crystalline semiconductor material using single-crystalline pillars as seeds. Another advantage is that the single-crystalline semiconductor can act as active regions of transistors (e.g., FinFETs, GAA FETs or planar FETs), thus forming a 3D IC having lower transistors at a lower level and higher transistors at a higher level.

In some embodiments, an IC structure includes a first transistor (e.g., transistor 504) formed on a substrate, a dielectric layer (e.g., ILD layer 104) above the first transistor, a plurality of first semiconductor pillars (e.g., raised semiconductor pillars 103) disposed over the substrate and extending through the dielectric layer, a semiconductor structure (e.g., fin 108) disposed over the top surface of the dielectric layer, and a second transistor (e.g., upper-level transistor 200) formed on the semiconductor structure. In some embodiments, one of the plurality of first semiconductor pillars has a top surface higher than a topmost position of the first transistor. In some embodiments, one of the first semiconductor pillars has up-slant facets and down-slant facets below the up-slant facets. In some embodiments, said one of the first semiconductor pillars has a top horizontal facet connecting the up-slant facets. In some embodiments, one of the up-slant facets is larger than the top horizontal facet in a cross-sectional view. In some embodiments, one of the up-slant facets is larger than one of the down-slant facets in a cross-sectional view. In some embodiments, the IC structure further includes a plurality of second semiconductor pillars (e.g., semiconductor pillars 101) disposed directly below the plurality of first semiconductor pillars in a one-to-one manner. In some embodiments, a maximal horizontal dimension of one of the plurality of first semiconductor pillars is larger than a maximal horizontal dimension of one of the plurality of second semiconductor pillars. In some embodiments, one of the plurality of second semiconductor pillars has a sidewall non-parallel with up-slant facets and down-slant facets of one of the plurality of first semiconductor pillars. In some embodiments, one of the plurality of second semiconductor pillars has a height less than a height of one of the plurality of first semiconductor pillars.

In some embodiments, an IC structure a first transistor (e.g., transistor 504) on a substrate; an interconnect structure (e.g., multilevel interconnect structures 50A and 50B) over the first transistor, the interconnect structure comprising a conductive via (e.g., via 53A) vertically extending above the substrate and a conductive line (e.g., conductive line 54A) laterally extending above the conductive via; a first semiconductor pillar (e.g., raised semiconductor pillar 103) disposed on the substrate and having a top surface at a position higher than the conductive via and the conductive line; a first dielectric layer (e.g., ILD layer 104) laterally surrounding an upper portion of the first semiconductor pillar and having a top surface substantially level with the top surface of the first semiconductor pillar; and a second transistor (e.g., upper-level transistor 200) disposed above the semiconductor first semiconductor pillar. In some embodiments, the IC structure further includes a STI region (e.g., STI region 102) laterally surrounding a lower portion of a fin of the first transistor. The first semiconductor pillar has a bottom surface interfacing the STI region. In some embodiments, the IC structure further includes a second semiconductor pillar (e.g., semiconductor pillar 101) having a lower portion laterally surrounded by the STI region and an upper portion protruding above the STI region. The first semiconductor pillar wraps around the upper portion of the second semiconductor pillar. In some embodiments, the second semiconductor pillar has a different cross-sectional shape than the first semiconductor pillar. In some embodiments, the IC structure further includes a second dielectric layer (e.g., dielectric layer 124) over the first dielectric layer; and a semiconductor plug (e.g., semiconductor plug 125) extending through the second dielectric layer to the first semiconductor pillar. In some embodiments, the second dielectric layer has a dielectric constant greater than a dielectric constant of the first dielectric layer. In some embodiments, the semiconductor plug has a maximal horizontal dimension less than a maximal horizontal dimension of the first semiconductor pillar.

In some embodiments, a method includes forming a first semiconductor pillar (e.g., raised semiconductor pillar 103) above a substrate; depositing a dielectric layer (e.g., ILD layer 104) over the first semiconductor pillar; planarizing the dielectric layer until a top surface of the first semiconductor pillar is exposed; depositing a non-single crystalline semiconductor material (e.g., non-crystalline layer 105) on the first semiconductor pillar; performing an anneal process to crystallize the non-single crystalline semiconductor material into a single-crystalline semiconductor material (e.g., single-crystalline layer 107); and forming a transistor (e.g., upper-level transistor 200) on the single-crystalline semiconductor material. In some embodiments, the method further includes forming a second semiconductor pillar (e.g., semiconductor pillar 103) on the substrate. The first semiconductor pillar is formed on the first semiconductor pillar. In some embodiments, the first semiconductor pillar is formed by etching trenches in the substrate to define the first semiconductor pillar, and the second semiconductor pillar is formed by epitaxially growing a semiconductor material from the first semiconductor pillar.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit (IC) structure comprising:
a first transistor formed on a substrate;
a dielectric layer above the first transistor;
a plurality of first semiconductor pillars disposed over the substrate and extending through the dielectric layer;
a semiconductor structure disposed over the dielectric layer; and
a second transistor formed on the semiconductor structure.

2. The IC structure of claim 1, wherein one of the plurality of first semiconductor pillars has a top surface higher than a topmost position of the first transistor.

3. The IC structure of claim 1, wherein one of the first semiconductor pillars has up-slant facets and down-slant facets below the up-slant facets.

4. The IC structure of claim 3, wherein said one of the first semiconductor pillars has a top horizontal facet connecting the up-slant facets.

5. The IC structure of claim 1, wherein the plurality of first semiconductor pillars are silicon-containing pillars.

6. The IC structure of claim 1, wherein the plurality of first semiconductor pillars are germanium-containing pillars.

7. The IC structure of claim 1, further comprising:
a plurality of second semiconductor pillars disposed directly below the plurality of first semiconductor pillars in a one-to-one manner.

8. The IC structure of claim 7, wherein a maximal horizontal dimension of one of the plurality of first semiconductor pillars is larger than a maximal horizontal dimension of one of the plurality of second semiconductor pillars.

9. The IC structure of claim 7, wherein one of the plurality of second semiconductor pillars has a sidewall non-parallel with up-slant facets and down-slant facets of one of the plurality of first semiconductor pillars.

10. The IC structure of claim 7, wherein one of the plurality of second semiconductor pillars has a height less than a height of one of the plurality of first semiconductor pillars.

11. An IC structure comprising:
a first transistor on a substrate;
an interconnect structure over the first transistor, the interconnect structure comprising a conductive via vertically extending above the substrate and a conductive line laterally extending above the conductive via;
a first semiconductor pillar disposed on the substrate and having a top surface at a position higher than the conductive via and the conductive line;
a first dielectric layer laterally surrounding an upper portion of the first semiconductor pillar and having a top surface substantially level with the top surface of the first semiconductor pillar; and
a second transistor disposed above the first semiconductor pillar.

12. The IC structure of claim 11, further comprising:
a shallow trench isolation (STI) region laterally surrounding a lower portion of a fin of the first transistor, wherein the first semiconductor pillar has a bottom surface interfacing the STI region.

13. The IC structure of claim 12, further comprising:
a second semiconductor pillar having a lower portion laterally surrounded by the STI region, and an upper portion protruding above the STI region, wherein the first semiconductor pillar wraps around the upper portion of the second semiconductor pillar.

14. The IC structure of claim 13, wherein the second semiconductor pillar has a different cross-sectional shape than the first semiconductor pillar.

15. The IC structure of claim 11, further comprising:
a second dielectric layer over the first dielectric layer; and
a semiconductor plug extending through the second dielectric layer to the first semiconductor pillar.

16. The IC structure of claim 15, wherein the second dielectric layer has a dielectric constant greater than a dielectric constant of the first dielectric layer.

17. The IC structure of claim 15, wherein the semiconductor plug has a maximal horizontal dimension less than a maximal horizontal dimension of the first semiconductor pillar.

18. A method comprising:
forming a first semiconductor pillar above a substrate;
depositing a dielectric layer over the first semiconductor pillar;
planarizing the dielectric layer until a top surface of the first semiconductor pillar is exposed;
depositing a non-single crystalline semiconductor material over the first semiconductor pillar;
performing an anneal process to crystallize the non-single crystalline semiconductor material into a single-crystalline semiconductor material; and
forming a transistor on the single-crystalline semiconductor material.

19. The method of claim 18, further comprising:
forming a second semiconductor pillar on the substrate, wherein the first semiconductor pillar is formed over the first semiconductor pillar.

20. The method of claim 19, wherein the first semiconductor pillar is formed by etching trenches in the substrate to define the first semiconductor pillar, and the second semiconductor pillar is formed by epitaxially growing a semiconductor material from the first semiconductor pillar.
